(19) United States
(12) Patent Application Publication
(10) Pub. No.: US 2026/0213458 A1
(43) Pub. Date: Jul. 23, 2026

(54) ELECTRICAL CONNECTION UNIT

(71) Applicant: YAZAKI CORPORATION, Tokyo (JP)

(72) Inventors: Kazuhiro Naito, Kakegawa-shi (JP); Ryu Senoo, Kakegawa-shi (JP); Yoshitake Mitsuhashi, Kakegawa-shi (JP)

(21) Appl. No.: 19/455,372

(22) Filed: Jan. 21, 2026

(30) Foreign Application Priority Data
Jan. 23, 2025 (JP) 2025-009686

(51) Int. Cl. H01R 13/533

(52) U.S. Cl. CPC H01R 13/533; H01R 2201/26

(57) ABSTRACT

An electrical connection unit is an electrical connection unit adjacent to a cooling unit at least when mounted on a vehicle, and includes a first routing structure, a first metal member, one or more electronic components, and a second metal member. The first routing structure includes one or more routing members and faces the cooling unit. The first metal member includes a first plate portion located on a side opposite to the cooling unit with respect to at least a part of the first routing structure. The one or more electronic components are disposed between the first plate portion and the first routing structure. The second metal member is disposed between the first plate portion and the first routing structure, and forms at least a part of a heat transfer path thermally connecting the first plate portion to the cooling unit.

### BACKGROUND OF THE INVENTION

### Field of the Invention

Embodiments of the present disclosure relate to an electrical connection unit.

Priority is claimed on Japanese Patent Application No. 2025-009686 filed in Japan on January 23, 2025, the content of which is incorporated herein by reference.

### Description of Related Art

In an electrical connection unit, electronic components such as a relay and a resistor are mounted on a bottom wall of a housing.

### Prior art Document

### Patent document

Patent Document 1: Japanese Unexamined Patent Application, First Publication No. 2018-113184

### SUMMARY OF THE INVENTION

Incidentally, it is expected to further improve a heat dissipation property of an electrical connection unit.

An embodiment provides an electrical connection unit capable of improving a heat dissipation property.

An electrical connection unit according to an embodiment is an electrical connection unit adjacent to a cooling unit at least when mounted on a vehicle, and includes a first routing structure, a first metal member, one or more electronic components, and a second metal member. The first routing structure includes one or more routing members and faces the cooling unit. The first metal member includes a first plate portion located on a side opposite to the cooling unit with respect to at least a part of the first routing structure. The one or more electronic components are disposed between the first plate portion and the first routing structure. The second metal member is disposed between the first plate portion and the first routing structure, and forms at least a part of a heat transfer path thermally connecting the first plate portion to the cooling unit.

According to one embodiment, it is possible to improve a heat dissipation property of an electrical connection unit.

### BRIEF DESCRIPTION OF THE DRAWINGS

FIG. 1 is a perspective view illustrating an electrical connection unit according to a first embodiment.

FIG. 2 is a partially exploded perspective view illustrating the electrical connection unit according to the first embodiment.

FIG. 3 is another partially exploded perspective view illustrating the electrical connection unit according to the first embodiment.

FIG. 4 is a perspective view for describing an electronic component and a connection component according to the first embodiment.

FIG. 5 is a partially exploded perspective view illustrating a first structure according to the first embodiment.

FIG. 6 is a perspective view illustrating a routing board according to the first embodiment.

FIG. 7 is a plan view illustrating the routing board according to the first embodiment.

FIG. 8 is a cross-sectional view of a structure taken along line F8-F8 in FIG. 7;

FIG. 9 is a cross-sectional view additionally illustrating a partial constitution of the electrical connection unit in FIG. 8.

FIG. 10 is a partially exploded perspective view illustrating a second structure according to the first embodiment.

FIG. 11 is an exploded perspective view illustrating the first structure and a metal member according to the first embodiment.

FIG. 12 is a partially exploded perspective view of an electrical connection unit according to a second embodiment.

FIG. 13 is a cross-sectional view illustrating the electrical connection unit according to the second embodiment.

FIG. 14 is a cross-sectional view illustrating an electrical connection unit according to a first modification example of the second embodiment.

FIG. 15 is a cross-sectional view illustrating an electrical connection unit according to a second modification example of the second embodiment.

### DETAILED DESCRIPTION OF THE INVENTION

Hereinafter, embodiments will be described with reference to the drawings. In the following description, constitutions having the same or similar functions are denoted by the same reference numbers. Redundant descriptions of these constitutions may be omitted. The constitutions to be described below do not limit the scope of the embodiment.

In the present disclosure, the terms are defined as follows. The term “connection” is not limited to a mechanical connection, and may include an electrical connection. That is, the term “connection” is not limited to a case where two elements that are connection targets are directly connected, and may include a case where two elements that are connection targets are connected with another element interposed therebetween. The term “accommodation” is not limited to a case where the entire component is accommodated, and may include a case where only a part of the component is accommodated (a state in which the remaining part of the component protrudes). The term “facing”, “overlapping”, or “adjacent” means that virtual projection images of two target objects overlap each other when viewed from a specific direction. For example, the term “facing” or “overlapping” is not limited to a case where two target objects directly face each other, and may include a case where two target objects face each other in a state in which another member or a gap exists between the two target objects. The term “adjacent” is not limited to a case where two objects are directly adjacent to each other, and may include a case where two objects are adjacent to each other in a state in which an electrical or thermal functional member (for example, an insulating sheet or a heat transfer sheet) exists between the two objects. “Parallel”, “orthogonal”, or “the same” may include “substantially parallel”, “substantially orthogonal”, or “substantially the same”, respectively.

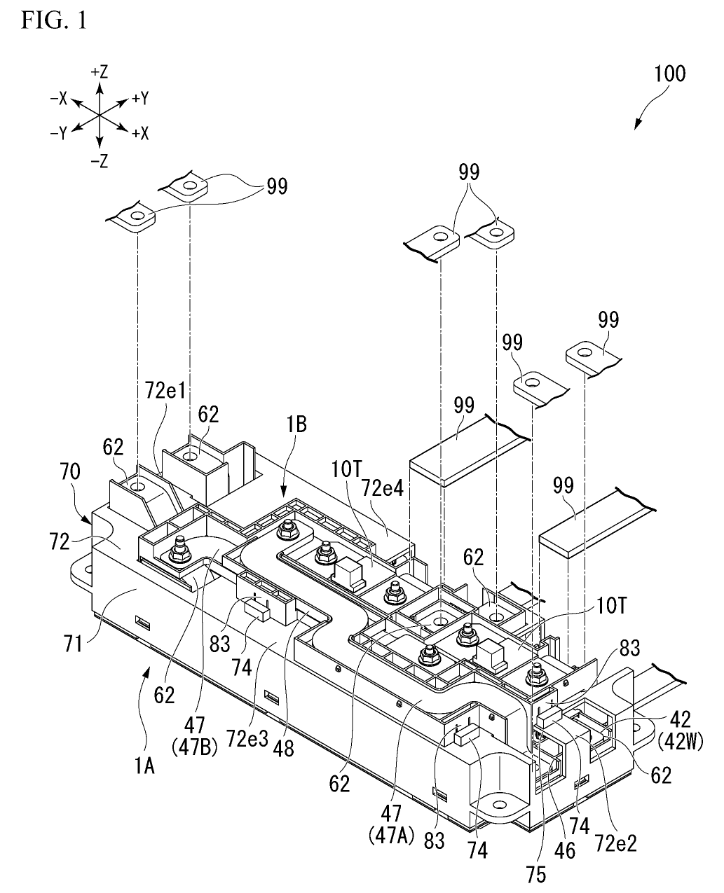

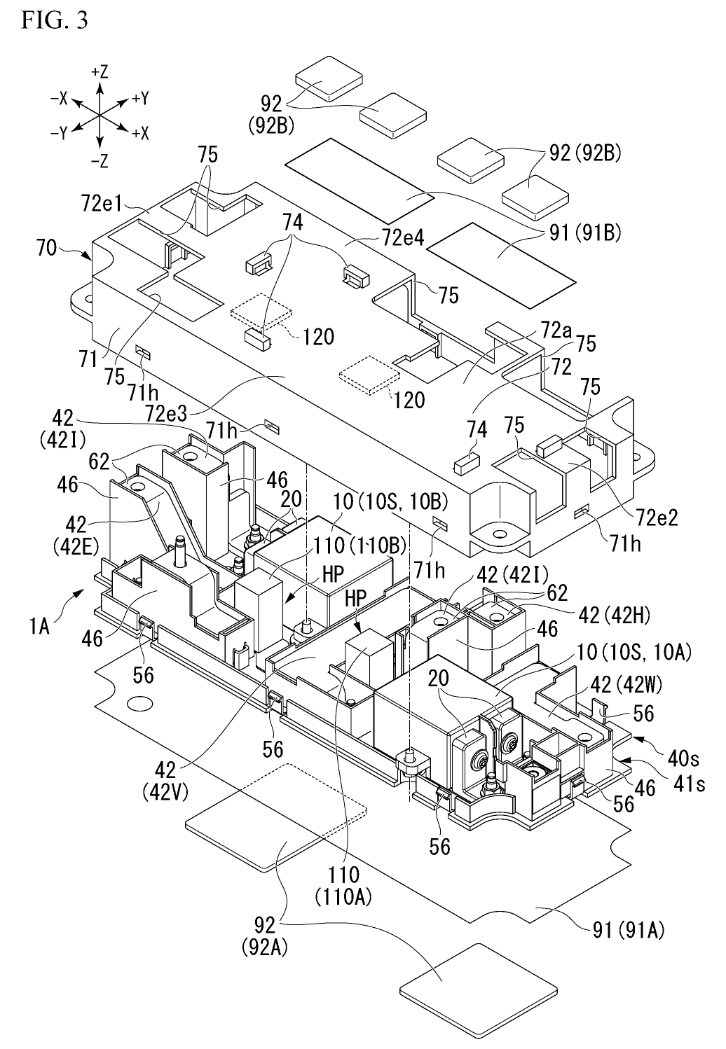

In the present disclosure, a +X direction, a -X direction, a +Y direction, a -Y direction, a +Z direction, and a -Z direction are defined as follows. The +X direction is a direction from a first end 72e1 to a second end 72e2 of a metal cover 70 described below (see FIG. 1). The -X direction is a direction opposite to the +X direction. Hereinafter, the +X direction and the -X direction are simply referred to as an “X direction” when they are not distinguished from each other. The +Y direction and the -Y direction are directions intersecting (for example, orthogonal to) the X direction. The +Y direction is a direction from a third end 72e3 to a fourth end 72e4 of the metal cover 70 described below (see FIG. 1). The -Y direction is a direction opposite to the +Y direction. Hereinafter, the +Y direction and the -Y direction are simply referred to as a “Y direction” when they are not distinguished from each other. The +Z direction and the -Z direction are directions intersecting (for example, orthogonal to) the X direction and the Y direction. The +Z direction is a direction from a routing board 40S described below toward a ceiling wall portion 72 of the metal cover 70 (see FIG. 3). The -Z direction is a direction opposite to the +Z direction. Hereinafter, the +Z direction and the -Z direction are simply referred to as “Z direction” when they are not distinguished from each other. The -Z direction is an example of a “first direction”. The X direction is an example of a “second direction”. The Y direction is an example of a “third direction”. The “second direction” is not limited to the X direction, and may be the Y direction or other directions. The “third direction” is not limited to the Y direction, and is a direction intersecting the “first direction” and the “second direction”.

Hereinafter, the X direction and the Y direction may be referred to as a “horizontal direction” when they are not distinguished from each other. Hereinafter, the Z direction may be referred to as a “vertical direction”. Hereinafter, a +Z direction side may be referred to as an “upper” side, and a -Z direction side may be referred to as a “lower” side. However, these expressions are expressions for convenience of description, and do not limit a gravity direction of an electrical connection unit 100 (an installation posture of the electrical connection unit 100).

### FIRST EMBODIMENT

### A1. Constitution of Electrical Connection Unit

The electrical connection unit 100 is, for example, in-vehicle equipment mounted on a vehicle such as an electric vehicle (EV), a hybrid electric vehicle (HEV), or a plug-in hybrid electric vehicle (PHEV). The electrical connection unit 100 may be referred to as an “electrical connection box” or a “junction box”, for example. However, the electrical connection unit 100 is not limited to a box-shaped device.

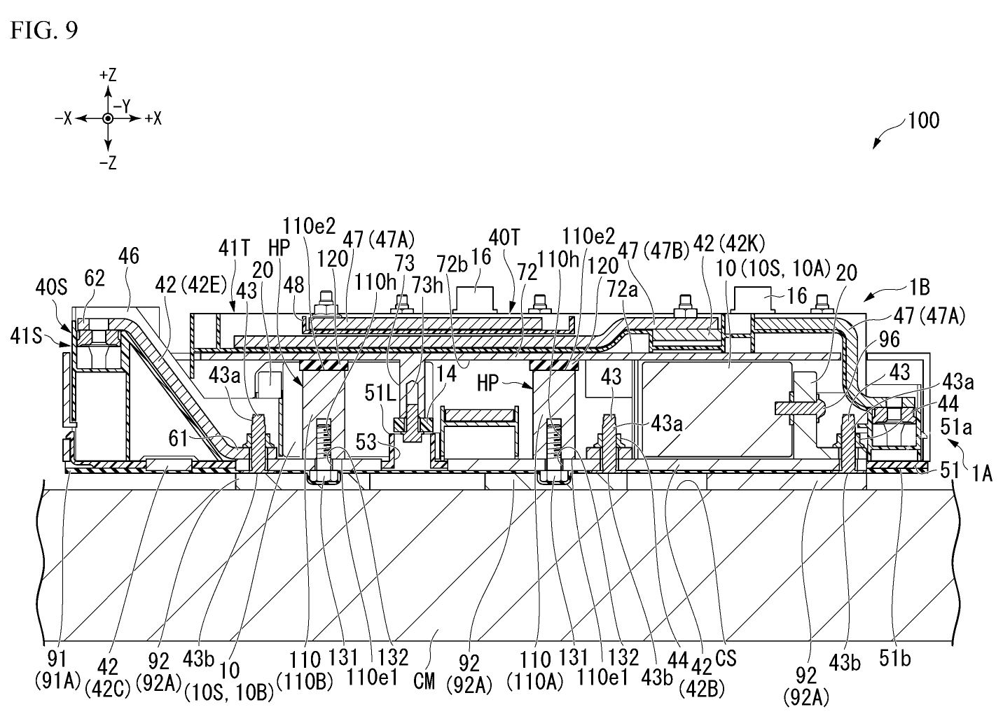

The electrical connection unit 100 is disposed in a state of being adjacent to an external cooling unit CM (see FIG. 9) at least when mounted on a vehicle (that is, when mounted on the vehicle). The cooling unit CM is, for example, a water jacket provided in a battery module. The cooling unit CM receives heat from the electrical connection unit 100 via a cooling surface CS of the cooling unit CM (see FIG. 9), and promotes cooling of the electrical connection unit 100. The cooling unit CM is not limited to the above example, and may be a cooling unit or the like provided exclusively for the electrical connection unit 100.

Next, a constitution of the electrical connection unit 100 will be described.

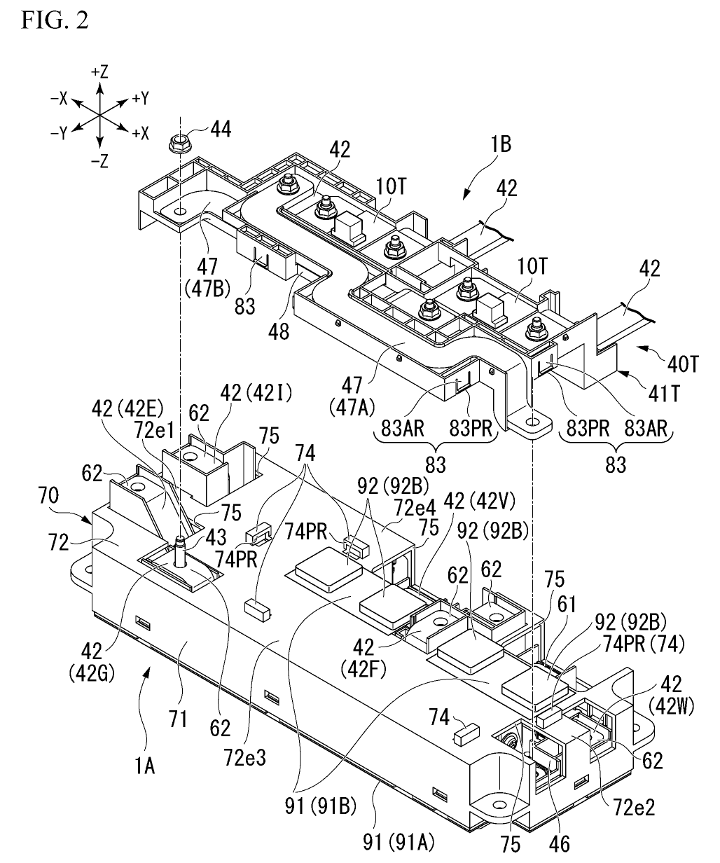

As illustrated in FIGS. 1 to 3, the electrical connection unit 100 includes, for example, a first structure 1A, a second structure 1B, a plurality of connection bus bars 47 (see FIG. 2), a second auxiliary member 48 (see FIG. 2), the metal cover 70, a plurality of insulating sheets 91 (see FIG. 3), a plurality of heat transfer members 92 (see FIG. 3), a plurality of metal blocks 110 (see FIG. 3), and a plurality of heat transfer members 120 (see FIG. 3). The electrical connection unit 100 may further include a cover that covers the second structure 1B from the +Z direction.

The first structure 1A is a unit forming a first-level portion, of a two-level hierarchical structure of the electrical connection unit 100. The second structure 1B is a unit forming a second-level portion, of the two-level hierarchical structure of the electrical connection unit 100. Hereinafter, in a case where an electronic component 10S and an electronic component 10T are not distinguished, the electronic components are simply referred to as an “electronic component 10”.

### A1.1 Constitution of First Structure

As illustrated in FIG. 3, the first structure 1A includes, for example, a plurality of electronic components 10S, a plurality of connection components 20, and the routing board 40S. The plurality of electronic components 10S are arranged on the +Z direction side with respect to at least a part of the routing board 40S. The electronic component 10S is electrically connected to the routing board 40S via the connection component 20. The routing board 40S faces the external cooling unit CM at least when mounted on the vehicle. The routing board 40S is an example of a “first routing structure”.

The first structure 1A faces the ceiling wall portion 72 of the metal cover 70 described below from the -Z direction side. The first structure 1A faces the cooling surface CS of the cooling unit CM from the +Z direction side. In the present disclosure, a first side and a second side are defined as follows. In a case where the -Z direction is the first direction, one side (for example, the -Z direction side) in the first direction is the first side, and the other side (for example, the +Z direction side) in the first direction is the second side.

### A1.2 Constitution of Second Structure

As illustrated in FIG. 2, the second structure 1B includes, for example, a plurality of electronic components 10T and a routing structure 40T. The routing structure 40T includes a cover member 41T and a plurality of bus bars 42. The plurality of electronic components 10T are disposed on the +Z direction side with respect to at least a part of the cover member 41T. The electronic component 10T is electrically connected to the bus bar 42 of the routing structure 40T. The routing structure 40T is an example of a “second routing structure”.

The second structure 1B is disposed on a side opposite to the first structure 1A and the cooling unit CM with respect to the ceiling wall portion 72 of the metal cover 70 (see FIG. 9). The second structure 1B faces the ceiling wall portion 72 of the metal cover 70 from the +Z direction side.

### A2. First Structure

Next, details of the first structure 1A will be described with reference to FIG. 3.

### A2.1 Electronic Component 10S

In the present embodiment, the plurality of electronic components 10 of the first structure 1A include the electronic component 10S. For example, the electronic component 10S is an electronic component whose amount of heat generation during energization is greater than that of the electronic component 10T. The electronic component 10S is a relay (for example, a mechanical relay or a semiconductor relay), a pyrofuse, or the like. However, the type of the electronic component 10S is not limited to the above example. An amount of heat generation when the electronic component 10S is energized may be smaller than an amount of heat generation when the electronic component 10T is energized. In the present embodiment, one or more (for example, a plurality of) electronic components 10S are disposed between the routing board 40S and the ceiling wall portion 72 of the metal cover 70. In the present embodiment, an electronic component 10A and an electronic component 10B are provided as the electronic components 10S. The electronic component 10A is an example of a “second electronic component”. The electronic component 10B is an example of a “first electronic component”.

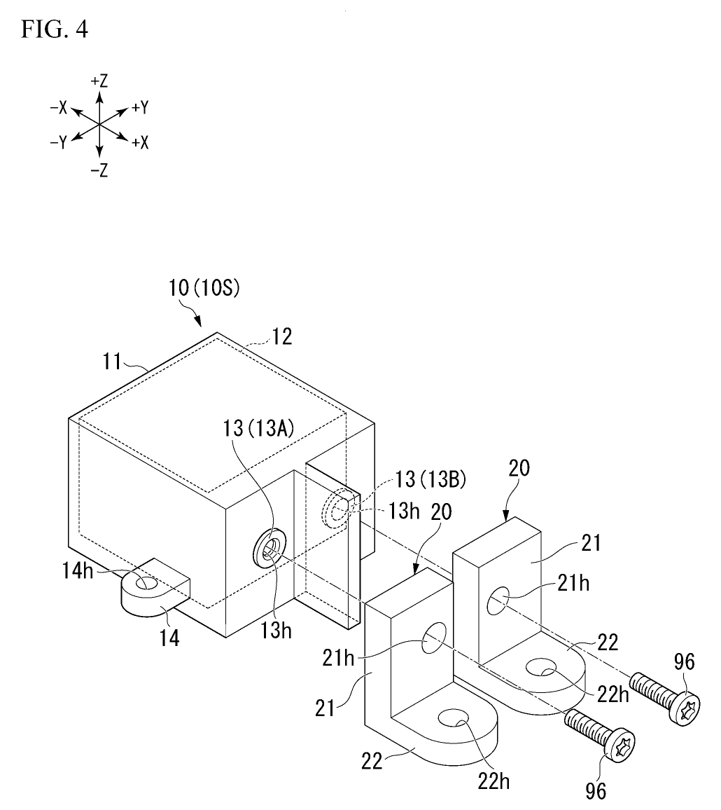

FIG. 4 is a perspective view illustrating the electronic component 10S and the connection component 20. The electronic component 10S is, for example, an electronic component in which a plurality of terminals 13 are disposed to be arranged at one end of the electronic component 10S. The electronic component 10S includes, for example, a case 11, a component body 12, the plurality of terminals 13, and a plurality of attachment portions 14.

### Case

The case 11 is an outer member that forms most of an outer shape of the electronic component 10S. The case 11 is made of, for example, a synthetic resin and has an insulating property. The case 11 accommodates the component body 12. The case 11 and the component body 12 may be integrally formed.

### Component Body

The component body 12 is a portion that performs a main function of the electronic component 10S. For example, in a case where the electronic component 10S is a relay, the component body 12 includes a switch (for example, a contact portion) that switches between a conductive state and a non-conductive state. For example, in a case where the electronic component 10S is a fuse, the component body 12 includes a fusion portion that is fused when an overcurrent flows. For example, in a case where the electronic component 10S is a capacitor, the component body 12 includes a portion that accumulates electric charges.

### Terminal

The terminal 13 is an electrical connection portion exposed to the outside of the case 11. The terminal 13 is electrically connected to the component body 12 inside the case 11. In the present embodiment, the electronic component 10S includes the terminal 13A and the terminal 13B as the plurality of terminals 13. One of the terminal 13A and the terminal 13B is a terminal on a positive electrode side. The other of the terminal 13A and the terminal 13B is a terminal on a negative electrode side.

In the electronic component 10S of the present embodiment, the terminal 13A and the terminal 13B are provided at one end of the electronic component 10S in the horizontal direction (for example, the X direction). The terminal 13A and the terminal 13B are disposed to be arranged in the horizontal direction (for example, the Y direction). Each of the terminal 13A and the terminal 13B is directed in the horizontal direction (for example, the X direction). Each terminal 13 has an attachment hole 13h to which a fastening member 96 (for example, a screw or a bolt) described below is attached. The attachment hole 13h is open in the horizontal direction (for example, the X direction). An inner circumferential surface of the attachment hole 13h of the electronic component 10S has a screw groove.

### Attachment Portion

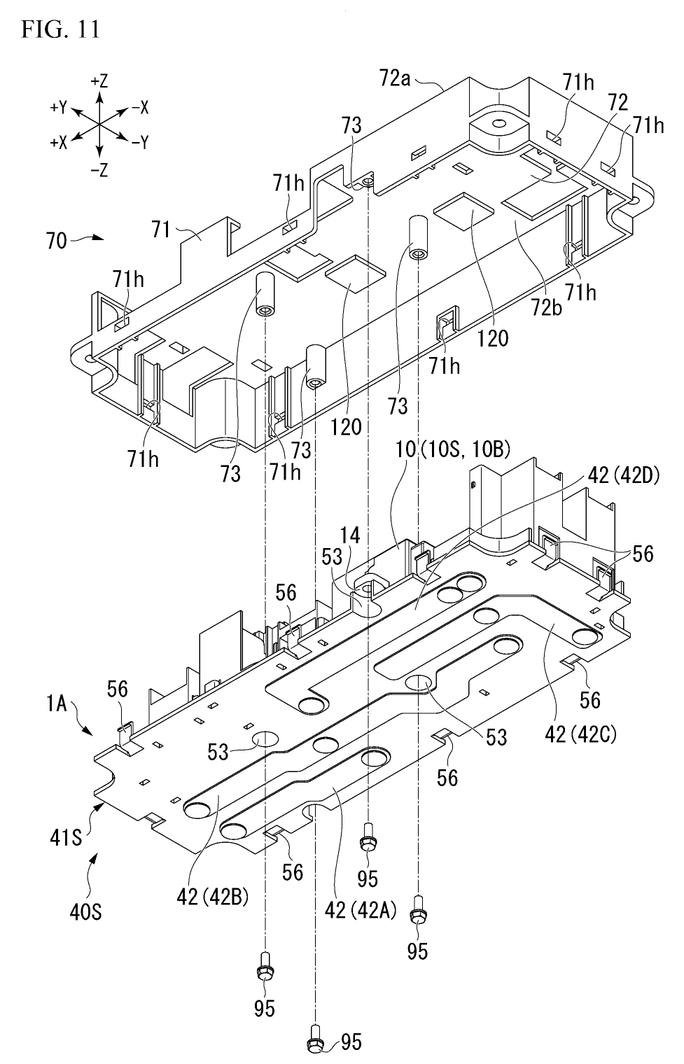

The attachment portion 14 is a portion for fixing the electronic component 10S. The attachment portion 14 has an attachment hole 14h to which a fastening member 95 (for example, a screw or a bolt; and see FIG. 11) described below is attached. The attachment hole 14h is open in the Z direction. The attachment hole 14h is an insertion hole through which the fastening member 95 passes. The attachment hole 14h faces an attachment hole 73h (see FIG. 9) of a fixing portion 73 described below.

### A2.2 Connection Component

Next, the connection component 20 will be described. The connection component 20 is a component electrically connecting the electronic component 10S to the bus bar 42 included in the routing board 40S. The connection component 20 forms a part of an energization path in the first structure 1A. The connection component 20 in the present disclosure is a member forming the energization path in the vertical direction. The connection component 20 is made of metal (for example, copper, a copper alloy, aluminum, or an aluminum alloy). The connection component 20 may also be referred to as a “vertical routing member”. The connection component 20 includes, for example, a first portion 21 and a second portion 22. In the present embodiment, the first portion 21 and the second portion 22 form one L-shaped connection component 20.

### First Portion

The first portion 21 of the connection component 20 is a portion connected to the terminal 13 of the electronic component 10S. The first portion 21 is a plate-shaped or rectangular parallelepiped portion extending in the Z direction. The first portion 21 extends in the Z direction along one end (for example, an end in the X direction) of the electronic component 10S. The first portion 21 is a standing portion that stands in the Z direction with respect to the routing board 40S (for example, with respect to the bus bar 42 described below). The first portion 21 is adjacent to the electronic component 10S in the horizontal direction (for example, the X direction). For example, the first portion 21 is adjacent to the terminal 13 of the electronic component 10S in the horizontal direction (for example, the X direction), and is connected to the terminal 13 of the electronic component 10S from the horizontal direction (for example, the X direction).

The first portion 21 of the connection component 20 has an attachment hole 21h through which the fastening member 96 (for example, a screw or a bolt) passes. The attachment hole 21h is open in the horizontal direction (for example, the X direction). The fastening member 96 that has passed through the attachment hole 21h is engaged with the attachment hole 13h of the terminal 13 of the electronic component 10S, and thus, the first portion 21 is physically and electrically connected to the terminal 13 of the electronic component 10S.

### Second Portion

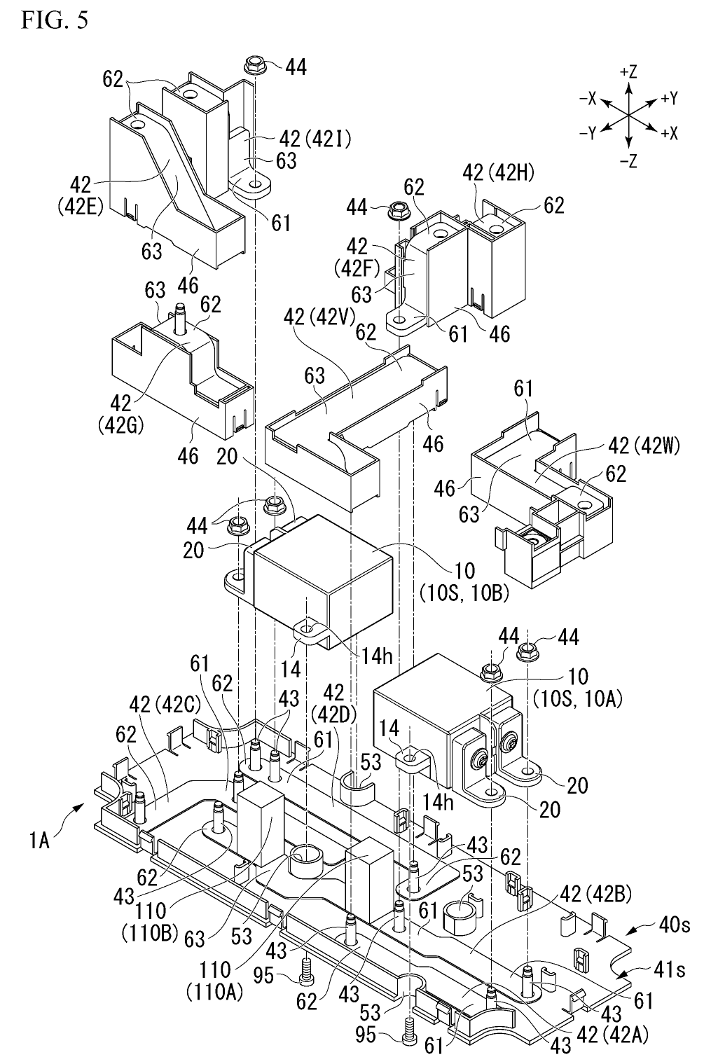

The second portion 22 of the connection component 20 is a portion connected to the bus bar 42 (see FIG. 5). The second portion 22 extends in the horizontal direction (for example, the X direction) from an end of the first portion 21 on the -Z direction side. The second portion 22 is a plate portion along the horizontal direction. The second portion 22 is adjacent to the bus bar 42 in the Z direction and is connected to the bus bar 42 from the Z direction (see FIG. 5). The second portion 22 of the connection component 20 is attached, from the Z direction, to a fastening member 43 (for example, a screw or bolt; and see FIG. 5) protruding from the bus bar 42 in the +Z direction, and is physically and electrically connected to the bus bar 42.

In the present embodiment, the second portion 22 of the connection component 20 has an attachment hole 22h through which the fastening member 43 passes. The attachment hole 22h is open in the Z direction. In the second portion 22, the fastening member 43 passes through the attachment hole 22h. An engagement member 44 (for example, a nut; and see FIG. 5) is engaged with a tip of the fastening member 43 that has passed through the attachment hole 22h, so that the second portion 22 is fixed to the bus bar 42.

### A2.3 Routing Board of First Structure

Next, the routing board 40S of the first structure 1A will be described.

FIG. 5 is a perspective view for describing the routing board 40S. The routing board 40S is a structure forming the energization path in the first structure 1A. For example, the routing board 40S forms the energization path to which the electronic component 10S included in the first structure 1A is connected. In the present embodiment, the routing board 40S has a plate shape extending in the X direction and the Y direction.

In the present disclosure, the “routing board” indicates a board-type routing board. The “board type” indicates a plate shape extending along one plane when viewed as a whole regardless of a fine shape. In the present disclosure, the term “plate shape”, “sheet shape”, or “planar” is not limited to the case of being completely flat, and may include a case where a fixing structure, a rib, or the like protruding in the Z direction is partially present, a case where an uneven shape following a thickness of the bus bar is present on the surface, and the like.

The routing board 40S includes one or more bus bars 42 and faces the cooling unit CM at least when mounted on the vehicle. The bus bar 42 is an example of a “routing member”. The routing board 40S includes, for example, a base member 41S, a plurality of bus bars 42, and a plurality of fastening members 43. In the present embodiment, the base member 41S and some bus bars 42 are integrated through insert molding. Note that the routing board 40S may be formed by using another structure instead of the insert molding. For example, the plurality of bus bars 42 may only be placed on an upper surface of the base member 41S and supported by the base member 41S from below.

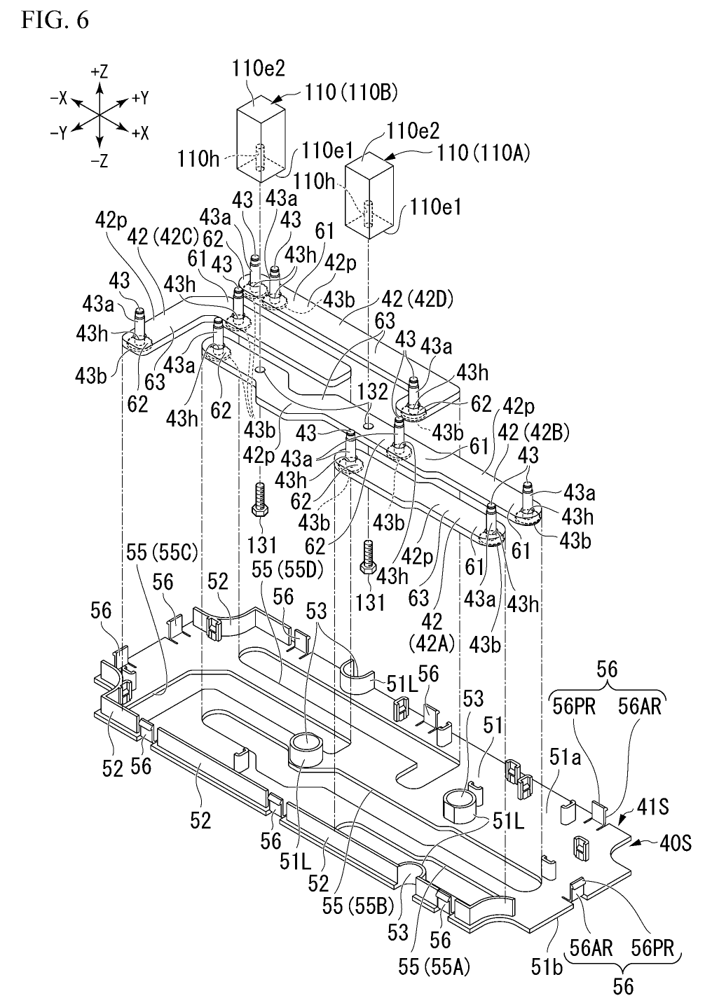

FIG. 6 is a partially exploded perspective view illustrating the routing board 40S. Hereinafter, for convenience of description, the base member 41S, the bus bar 42, and the fastening member 43 will be described with reference to the partially exploded drawing of the routing board 40S.

### A2.3.1 Base Member

The base member 41S is a support member that supports the plurality of electronic components 10S or/and the plurality of bus bars 42. The base member 41S in the present embodiment supports the bus bar 42 and indirectly supports the plurality of electronic components 10S via the connection components 20. The plurality of bus bars 42 are arranged in the horizontal direction at intervals. The base member 41S is made of, for example, a synthetic resin and has an insulating property. The base member 41S electrically insulates between the plurality of bus bars 42. The base member 41S includes, for example, a flat surface portion 51, a wall portion 52, and a plurality of opening portions 53.

### Flat Surface Portion

The flat surface portion 51 is a portion formed in a plate shape in the base member 41S. The flat surface portion 51 has a plate shape extending in the horizontal direction. The flat surface portion 51 forms a main portion of the base member 41S. The flat surface portion 51 forms a base portion (insulating base portion) of the base member 41S. In the present embodiment, the flat surface portion 51 extends over the entire width of the base member 41S in the X direction and over the entire width of the base member 41S in the Y direction, except for the wall portion 52 of the base member 41S.

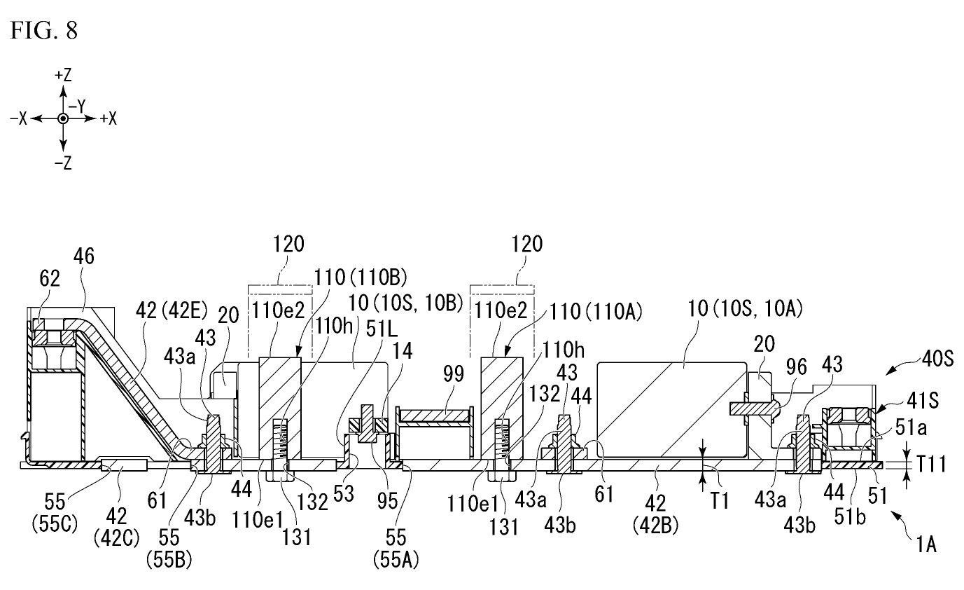

The flat surface portion 51 has a first surface 51a and a second surface 51b. The first surface 51a is a surface directed in the +Z direction. The first surface 51a is a flat surface along the horizontal direction. The first surface 51a faces the plurality of electronic components 10S from the -Z direction side, and faces the metal cover 70 (see FIG. 9) from the -Z direction side. The second surface 51b is located on a side opposite to the first surface 51a. The second surface 51b is a surface directed in the -Z direction. The second surface 51b is a flat surface along the horizontal direction. The second surface 51b faces the external cooling unit CM (see FIG. 9) from the +Z direction side. In the present embodiment, a thickness T11 of the flat surface portion 51 in the Z direction is smaller than a thickness T1 of the bus bar 42 in the Z direction (for example, a thickness of a horizontal plate portion 42p described below in the Z direction) (see FIG. 8). The thickness T11 of the flat surface portion 51 in the Z direction may be equal to the thickness T1 of the bus bar 42 in the Z direction, or may be larger than the thickness T1 of the bus bar 42 in the Z direction.

In the present embodiment, the flat surface portion 51 has a plurality of accommodation portions 55. The plurality of accommodation portions 55 are formed apart from each other in the X direction or the Y direction. Each accommodation portion 55 is, for example, a through-hole penetrating through the flat surface portion 51 in the Z direction. Note that the accommodation portion 55 may be a recess provided on the first surface 51a or the second surface 51b of the flat surface portion 51 and recessed in the Z direction, instead of a through-hole. In the present disclosure, the phrase “the accommodation portion penetrates through the flat surface portion in the first direction (Z direction)” may include a case where a part of the entire length of the accommodation portion 55 penetrates through the flat surface portion 51 in the Z direction (for example, the remaining portion of the accommodation portion 55 may be a recess recessed in the Z direction, or may be provided inside the base member 41S and not exposed to the outside of the base member 41S). Similarly, in the present disclosure, the phrase “the accommodation portion is recessed in the first direction (Z direction)” may include a case where a part of the entire length of the accommodation portion 55 is recessed in the Z direction (for example, the remaining portion of the accommodation portion 55 may be a through-hole penetrating through the flat surface portion 51 in the Z direction, or may be provided inside the base member 41S and not exposed to the outside of the base member 41S).

Each accommodation portion 55 has an outer shape corresponding to a shape of the bus bar 42 to be accommodated when viewed from the Z direction. The plurality of accommodation portions 55 include, for example, four accommodation portions 55A, 55B, 55C, and 55D. The accommodation portion 55A is provided to correspond to the bus bar 42A described below, and accommodates at least a part of the bus bar 42A. The accommodation portion 55B is provided to correspond to the bus bar 42B described below, and accommodates at least a part of the bus bar 42B. The accommodation portion 55C is provided to correspond to the bus bar 42C described below, and accommodates at least a part of the bus bar 42C. The accommodation portion 55D is provided to correspond to the bus bar 42D described below, and accommodates at least a part of the bus bar 42D.

The flat surface portion 51 has one or more locking portions 56. The locking portion 56 is used for locking the metal cover 70 and the first structure 1A. An example of the locking portion 56 is a fitting claw (also referred to as a “snap-fit”). The fitting claw includes an arm portion 56AR extending in the +Z direction from the flat surface portion 51 and a protruding portion 56PR protruding as a part of the arm portion 56AR. The protruding portion 56PR protrudes from the arm portion 56AR in a direction intersecting an extending direction (+Z direction) of the arm portion 56AR. In the present embodiment, the protruding portion 56PR protrudes toward the metal cover 70 and is locked to a holding portion 71h described below (see FIG. 3).

### Wall Portion

The wall portion 52 is provided at a peripheral end of the base member 41S. The wall portion 52 is a reinforcement rib protruding in the +Z direction from an end of the flat surface portion 51. The wall portion 52 may be used for positioning the first structure 1A and the metal cover 70 at the time of assembly. Note that the wall portion 52 may be omitted.

### Opening Portion

The opening portion 53 is an opening facing the attachment hole 73h of the fixing portion 73 of the metal cover 70 and the attachment hole 14h of the attachment portion 14 of the electronic component 10S described below (see FIGS. 5, 9, 11, and the like). The opening portion 53 penetrates through the base member 41S in the Z direction. The fastening member 95 (for example, a screw or a bolt) described below passes through the opening portion 53. This content will be described later. The opening portion 53 may be an opening formed in a notched shape through which the fastening member 95 can be inserted.

The base member 41S may have a rib 51L protruding from the flat surface portion 51 in the +Z direction around the opening portion 53. The rib 51L may be able to support the attachment portion 14 of the electronic component 10S from the -Z direction.

### First Auxiliary Member

The routing board 40S may further include one or more first auxiliary members 46 as necessary. As illustrated in FIG. 5, the first auxiliary member 46 is a support member that assists three-dimensional routing of some bus bars 42 (for example, the bus bars 42 corresponding to “three-dimensional routing members” described below). The first auxiliary member 46 supports the bus bar 42 from the -Z direction side. The first auxiliary member 46 supports a second connection portion 62 of the bus bar 42 to a position away from a first connection portion 61 of the bus bar 42 (for example, a position away in the Z direction). The first auxiliary member 46 is made of, for example, a synthetic resin and has an insulating property.

### A2.3.2 Bus Bar

Next, the bus bar 42 included in the routing board 40S will be described. The bus bar 42 is a routing member (electrical connection member) of the electrical connection unit 100. The bus bar 42 included in the routing board 40S is electrically connected to, for example, at least one electronic component 10S included in the plurality of electronic components 10S. For example, each of some bus bars 42 electrically connects two electronic components 10 included in the plurality of electronic components 10 (for example, the plurality of electronic components 10S). The bus bar 42 is made of metal (for example, copper, a copper alloy, aluminum, or an aluminum alloy) and has conductivity. The bus bar 42 is an example of a “routing member”.

In the present embodiment, the plurality of bus bars 42 included in the first structure 1A include, for example, 11 bus bars 42A, 42B, 42C, 42D, 42E, 42F, 42G, 42H, 42I, 42V, and 42W (see FIGS. 5 and 6).

As illustrated in FIG. 6, four bus bars 42A, 42B, 42C, and 42D are disposed to be arranged at intervals in the horizontal direction. The four bus bars 42A, 42B, 42C, and 42D include portions disposed on the same plane. The four bus bars 42A, 42B, 42C, and 42D are supported by the flat surface portion 51 of the base member 41S. In the present disclosure, the phrase “the bus bar is supported by the flat surface portion” is not limited to a case where the bus bar 42 is accommodated in the accommodation portion 55, and may include a case where the bus bar 42 is attached to the first surface 51a or the second surface 51b of the flat surface portion 51. The four bus bars 42A, 42B, 42C, and 42D are integrated with the base member 41S through insert molding.

At least a part of each bus bar 42 has a plate shape extending in the horizontal direction. For example, at least a part of each of the four bus bars 42A, 42B, 42C, and 42D is accommodated in the accommodation portion 55 and extends along the flat surface portion 51. That is, at least a part of each of the four bus bars 42A, 42B, 42C, and 42D extends along the first surface 51a of the flat surface portion 51. At least a part of each of the four bus bars 42A, 42B, 42C, and 42D extends in the horizontal direction in the accommodation portion 55. Hereinafter, a portion of each of the four bus bars 42, which extends in a plate shape extending in the horizontal direction, may be referred to as the “horizontal plate portion 42p”. The horizontal plate portion 42p is an example of a “plate portion”. The four bus bars 42A, 42B, 42C, and 42D are members forming energization paths in the horizontal direction. The four bus bars 42A, 42B, 42C, and 42D may be referred to as the “horizontal routing members”. At least a part of the bus bar 42 corresponding to the “horizontal routing member” extends in the horizontal direction in the accommodation portion 55. As a result, the energization path in the horizontal direction is formed in the routing board 40S. For example, each of the bus bar 42A and the bus bar 42B is electrically connected to the terminal 13 of the electronic component 10A via the connection component 20. Each of the bus bar 42C and the bus bar 42D is electrically connected to the terminal 13 of the electronic component 10B via the connection component 20.

In the present embodiment, the four bus bars 42A, 42B, 42C, and 42D are located on the -Z direction side with respect to the electronic component 10 (for example, the electronic component 10S) of the first structure 1A. That is, the four bus bars 42A, 42B, 42C, and 42D are located on a side opposite to the ceiling wall portion 72 of the metal cover 70 with respect to the electronic component 10 (for example, the electronic component 10S) of the first structure 1A.

In the present embodiment, the four bus bars 42A, 42B, 42C, and 42D are accommodated in the accommodation portion 55 of the base member 41S and exposed to an upper surface side and a lower surface side of the base member 41S. That is, surfaces of the four bus bars 42A, 42B, 42C, and 42D on the +Z direction side are exposed to the upper surface side of the base member 41S and face the metal cover 70. On the other hand, surfaces of the four bus bars 42A, 42B, 42C, and 42D on the -Z direction side are exposed to the outside of the electrical connection unit 100 and face the cooling unit CM.

As illustrated in FIG. 5, seven bus bars 42E, 42F, 42G, 42H, 42I, 42V, and 42W are three-dimensionally routed at intervals. The seven bus bars 42E, 42F, 42G, 42H, 42I, 42V, and 42W are supported by the first auxiliary members 46. The first connection portion 61 and the second connection portion 62 of each of the seven bus bars 42E, 42F, 42G, 42H, 42I, 42V, and 42W extend in the horizontal direction on the first auxiliary member 46. The seven bus bars 42E, 42F, 42G, 42H, 42I, 42V, and 42W are the bus bars 42 forming energization paths in the vertical direction. The seven bus bars 42E, 42F, 42G, 42H, 42I, 42V, and 42W may be referred to as the “three-dimensional routing members”. In the bus bar 42 corresponding to the “three-dimensional routing member”, the second connection portion 62 of the bus bar 42 is at a position away from the first connection portion 61 (for example, a position away in the Z direction). As a result, the energization path in the vertical direction is formed in the routing board 40S.

As illustrated in FIGS. 5 to 7, each bus bar 42 includes, for example, the first connection portion 61, the second connection portion 62, and an extending portion 63.

The first connection portion 61 is located at the middle of the bus bar 42 or at a first end of the bus bar 42. The first connection portion 61 is a portion connected to the electronic component 10 (for example, the electronic component 10S) directly or via the connection component 20. Instead of the above example, the first connection portion 61 may be connected to another bus bar 42 (for example, a bus bar 42 different from the bus bar 42 connected to the electronic component 10). Instead of the above example, the first connection portion 61 (for example, the first connection portion 61 of the bus bar 42W) may be connected to an external connection bus bar 99 (see FIGS. 1 to 3). The external connection bus bar 99 is an example of a “routing member”.

The second connection portion 62 is located at the middle of the bus bar 42 or at a second end of the bus bar 42. The second connection portion 62 is a portion connected to the electronic component 10 (for example, the electronic component 10S) directly or via another connection component 20. Instead of the above example, the second connection portion 62 may be connected to another bus bar 42 (for example, a bus bar 42 different from the bus bar 42 connected to the electronic component 10). In addition, instead of the above example, the second connection portion 62 may be connected to the connection bus bar 47 or the external connection bus bar 99 (see FIGS. 1 and 2). For example, the second connection portion 62 is connected to external equipment via the external connection bus bar 99. The external connection bus bar 99 is an example of an “external connection component”. Each of the connection bus bar 47 and the external connection bus bar 99 is an example of a “routing member”.

The extending portion 63 extends over the first connection portion 61 and the second connection portion 62. The extending portion 63 is provided between the first connection portion 61 and the second connection portion 62. The extending portion 63 connects the first connection portion 61 to the second connection portion 62.

In the present embodiment, the horizontal plate portion 42p described above includes at least the entire first connection portion 61 and a part of the extending portion 63. For example, the horizontal plate portion 42p includes the first connection portion 61, the second connection portion 62, and the extending portion 63. In the present embodiment, in the four bus bars 42A, 42B, 42C, and 42D, the first connection portion 61, the second connection portion 62, and the extending portion 63 are accommodated in the accommodation portion 55 and located on the same plane.

### A2.3.3 Fastening Member

Next, the fastening member 43 will be described.

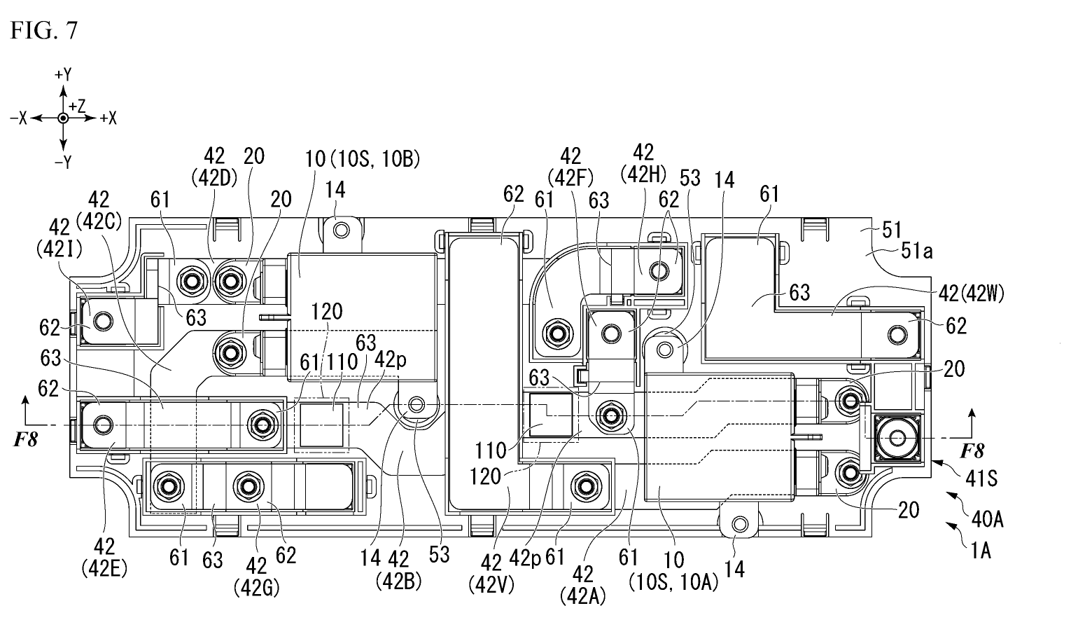

FIG. 8 is a cross-sectional view of a structure taken along line F8-F8 in FIG. 7. The fastening member 43 is a component for fixing the bus bar 42 to the connection component 20 corresponding to the bus bar 42. In addition, instead of the above example, the fastening member 43 may be a component for fixing the connection bus bar 47 or the external connection bus bar 99, and the bus bar 42. The fastening member 43 is, for example, a caulking bolt fixed to the bus bar 42. The fastening member 43 is an example of a “fastening portion”.

In some bus bars 42 of the present embodiment, at least one of the first connection portion 61 and the second connection portion 62 of the bus bar 42 has a through-hole 43h (see FIG. 6). The through-hole 43h penetrates through the bus bar 42 in the Z direction. The fastening member 43 is, for example, a bolt having a shaft 43a and a head 43b. A circumferential surface of the shaft 43a has a screw groove. The head 43b has a diameter larger than that of the shaft 43a. The head 43b of the fastening member 43 is caulked and fixed to the bus bar 42 in a state in which the shaft 43a passes through the through-hole 43h of the bus bar 42. With this fixation, the fastening member 43 is electrically and physically connected to the bus bar 42 in a state in which the shaft 43a protrudes in the +Z direction from the through-hole 43h of the bus bar 42. The fastening member 43 is not limited to caulking fixation and may be fixed to the bus bar 42 through welding or other methods.

### A3. Second Structure

Next, details of the second structure 1B will be described. The second structure 1B includes, for example, the routing structure 40T and one or more (for example, a plurality of) electronic components 10T.

The routing structure 40T is a structure forming an energization path in the second structure 1B. For example, the routing structure 40T forms the energization path to which the electronic component 10T is connected. The routing structure 40T faces the ceiling wall portion 72 of the metal cover 70 from a side opposite to the routing board 40S of the first structure 1A. The routing structure 40T is an example of a “second routing structure”. The routing structure 40T includes one or more cover members 41T and one or more bus bars 42. In the present embodiment, the routing structure 40T includes a plurality of cover members 41T and a plurality of bus bars 42.

### A3.1 Electronic Component 10T

In the present embodiment, the plurality of electronic components 10 of the second structure 1B include the electronic component 10T. The electronic component 10T is an electronic component whose amount of heat generation during energization is smaller than that of the electronic component 10S. The electronic component 10T is, for example, a connector, a fuse, a capacitor, a branch component, any of various sensors (for example, a current sensor or a voltage sensor), an electronic control unit, or an electronic component unit in which two or more of these are unitized. However, the type of the electronic component 10T is not limited to the above example. The amount of heat generation when the electronic component 10T is energized may be greater than the amount of heat generation when the electronic component 10S is energized. The electronic component 10T faces the ceiling wall portion 72 of the metal cover 70 from a side opposite to the routing board 40S of the first structure 1A. The electronic component 10T is an example of a “third electronic component”.

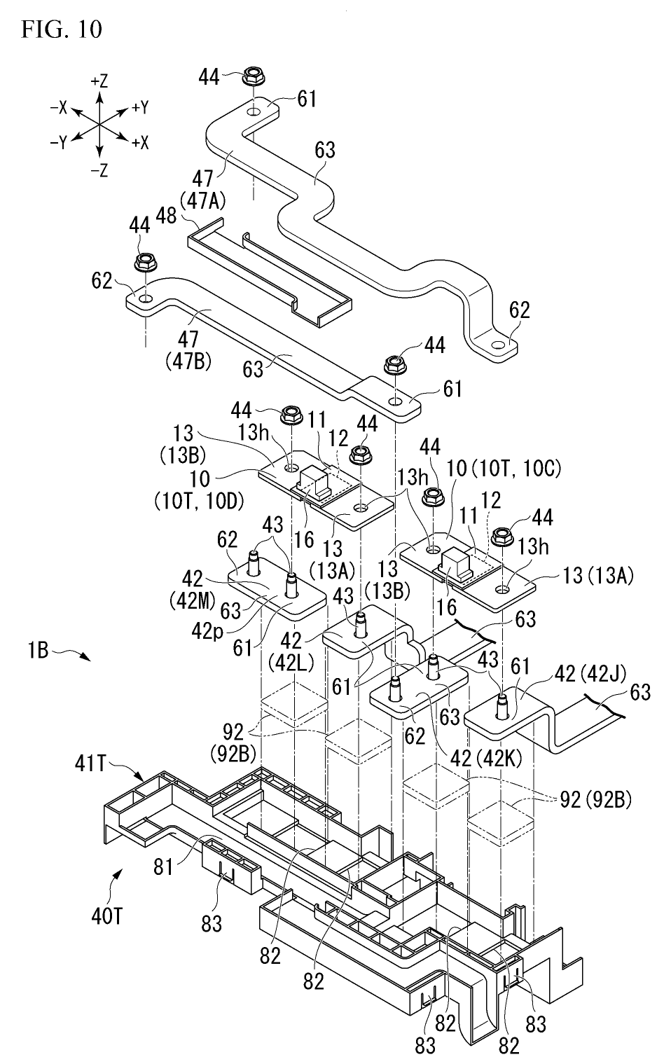

As illustrated in FIG. 10, the electronic component 10T in the present embodiment is, for example, a current sensor (for example, a current sensor including a shunt resistor). The electronic component 10T includes an output port 16 protruding in the +Z direction. When external equipment (for example, a control board or a measuring instrument) is electrically connected to the output port 16, a current value of a current flowing through the electrical connection unit 100 (for example, a current flowing through the first structure 1A) is monitored. For example, the electronic component 10T is an electronic component in which two terminals 13 are separately disposed at both ends of the electronic component 10T in the horizontal direction. The electronic component 10T includes, for example, a case 11, a component body 12, the plurality of terminals 13 (the terminal 13A and the terminal 13B), and the output port 16. Note that, among the constitutions of the electronic component 10T, constitutions having functions similar to those of the electronic component 10S are denoted by the same reference numbers. In this case, in the description regarding the electronic component 10T, the “electronic component 10S” may be replaced with the “electronic component 10T” in the description regarding the electronic component 10S described above.

In the electronic component 10T, the terminal 13A and the terminal 13B are disposed apart from each other in the horizontal direction (for example, the X direction). Each terminal 13 has an attachment hole 13h through which a fastening member 43 (for example, a screw or a bolt) passes. The attachment hole 13h is open in the Z direction.

### A3.2 Cover Member

Next, the cover member 41T of the second structure 1B will be described.

The cover member 41T covers a part of the bus bar 42 included in the second structure 1B. The cover member 41T is made of, for example, a synthetic resin and has an insulating property. The cover member 41T includes, for example, a wall portion 81 and one or more locking portions 83.

The wall portion 81 is, for example, a plate-shaped wall extending in the horizontal direction. The wall portion 81 covers a lower surface of an extending portion 63 (described below) of the connection bus bar 47 in the horizontal direction (for example, the X direction). The wall portion 81 is not limited to a wall portion extending in the horizontal direction and may be a grid-shaped wall portion formed by a plurality of ribs extending in the Z direction. In the present embodiment, the fastening member 43 fixed to the bus bar 42 is disposed on the wall portion 81. Further, the wall portion 81 may partially have a step. For example, in the present embodiment, two connection bus bars 47 are attached to the bus bar 42 of the second structure 1B. The two connection bus bars 47 three-dimensionally cross each other due to the step of the wall portion 81.

For example, the cover member 41T may include an accommodation portion 82 that is open toward the +Z direction side. The accommodation portion 82 is a through-hole penetrating through the wall portion 81 in the Z direction. The accommodation portion 82 has an outer shape corresponding to a shape of the heat transfer member 92 (for example, a heat transfer member 92B) described below when viewed from the Z direction. The accommodation portion 82 surrounds and accommodates the heat transfer member 92B adhering to the ceiling wall portion 72 (see FIGS. 2 and 10). Note that the heat transfer member 92B indicated by an imaginary line in FIG. 10 can be accommodated in the accommodation portion 82.

### Locking portion

The locking portion 83 is used for locking the metal cover 70 and the second structure 1B. Examples of the locking portion 83 include a fitting claw. The fitting claw includes an arm portion 83AR extending in the -Z direction from the wall portion 81 and a protruding portion 83PR protruding as a part of the arm portion 83AR (see FIG. 2). The protruding portion 83PR protrudes from the arm portion 83AR in a direction intersecting an extending direction (-Z direction) of the arm portion 83AR. In the present embodiment, the protruding portion 83PR protrudes toward the metal cover 70 and is locked to a holding portion 74 described below (see FIG. 1).

### A3.3 Bus Bar

Next, the bus bar 42 included in the second structure 1B will be described. The plurality of bus bars 42 in the second structure 1B include, for example, four bus bars 42J, 42K, 42L, and 42M (see FIG. 10). The four bus bars 42J, 42K, 42L, and 42M are disposed apart from each other in the horizontal direction. The four bus bars 42J, 42K, 42L, and 42M are supported by the wall portion 81 of the cover member 41T.

A part of the bus bar 42 overlaps the heat transfer member 92B when viewed from the Z direction. The heat transfer member 92B is made of a material having higher thermal conductivity than the cover member 41T, for example. The heat transfer member 92B has, for example, an insulating property. In the present embodiment, the heat transfer member 92B is disposed between the bus bar 42 and the ceiling wall portion 72 of the metal cover 70, and is in contact with each of the bus bar 42 and the ceiling wall portion 72 of the metal cover 70. The heat transfer member 92B thermally connects the bus bar 42 to the ceiling wall portion 72 of the metal cover 70. That is, a heat transfer path from the bus bar 42 to the metal cover 70 is formed via the heat transfer member 92B. The heat transfer member 92B is an example of a “second heat transfer member”.

In the present embodiment, a part of the bus bar 42 overlapping the heat transfer member 92B is located immediately below the terminal 13 of the electronic component 10. In other words, the heat transfer member 92B is disposed between the electronic component 10T and the ceiling wall portion 72 of the metal cover 70. For example, the heat transfer member 92B is disposed between the terminal 13 of the electronic component 10T and the ceiling wall portion 72 of the metal cover 70. The heat transfer member 92B transfers, from the bus bar 42 to the ceiling wall portion 72 of the metal cover 70, at least part of heat transferred from the terminal 13 of the electronic component 10T to the bus bar 42.

Instead of the above example, the heat transfer member 92B may be disposed between the electronic component 10T and the ceiling wall portion 72 of the metal cover 70 at a position deviated from a lower side of the bus bar 42. For example, the heat transfer member 92B may be in direct contact with the electronic component 10T. In another example, the heat transfer member 92B may be disposed between the bus bar 42 and the ceiling wall portion 72 of the metal cover 70 at a position deviated from a lower side of the electronic component 10T.

### A4. Connection Bus Bar

Next, the connection bus bar 47 will be described.

As illustrated in FIG. 10, the connection bus bar 47 is a routing member that links the first structure 1A to the second structure 1B and electrically connects the first structure 1A to the second structure 1B. At least one electronic component 10S included in the plurality of electronic components 10S included in the first structure 1A and at least one electronic component 10T included in the plurality of electronic components 10T included in the second structure 1B are electrically connected via the connection bus bar 47. In the present embodiment, the plurality of connection bus bars 47 include two connection bus bars 47A and 47B.

### A5. Second Auxiliary Member

As illustrated in FIG. 10, when two connection bus bars 47 are attached to the bus bars 42 (for example, the bus bars 42K and 42M) of the second structure 1B, the two connection bus bars 47 may be adjacent to each other in the Z direction. In this case, the second auxiliary member 48 is disposed between the two adjacent connection bus bars 47. The second auxiliary member 48 electrically insulates between the two connection bus bars 47 adjacent to each other in the Z direction. The second auxiliary member 48 is made of, for example, a synthetic resin and has an insulating property.

### A6. Constitution of Metal Cover

Next, a constitution of the metal cover 70 will be described.

The metal cover 70 is a member for securing rigidity of the electrical connection unit 100 and enhancing the heat dissipation property of the electrical connection unit 100. The metal cover 70 is made of metal (for example, aluminum or an aluminum alloy). The metal cover 70 is an example of a “first metal member”. The metal cover 70 may be referred to as a “rigid member” or a “heat dissipation member”.

As illustrated in FIGS. 3 and 11, the metal cover 70 covers the first structure 1A from the +Z direction. On the other hand, a lower surface of the base member 41S of the first structure 1A (for example, the second surface 51b of the flat surface portion 51) is not covered by the metal cover 70 and is exposed to the outside of the electrical connection unit 100. The metal cover 70 only needs to cover most of a main portion (described below) of the first structure 1A, and a part of the first structure 1A may be exposed through an insertion portion 75.

The metal cover 70 includes a peripheral wall 71, the ceiling wall portion 72, a plurality of fixing portions 73, one or more holding portions 74, and the insertion portion 75.

### Peripheral Wall

The peripheral wall 71 is a plate portion extending in the -Z direction from a peripheral end of the ceiling wall portion 72 in the horizontal direction. The peripheral wall 71 faces at least one electronic component 10S included in the plurality of electronic components 10S included in the first structure 1A when viewed from the X direction or the Y direction. For example, the peripheral wall 71 is formed in a frame shape along the peripheral end of the ceiling wall portion 72 in the horizontal direction, and surrounds the plurality of electronic components 10S included in the first structure 1A from four sides in the horizontal direction. The peripheral wall 71 is an example of a “second plate portion”.

The peripheral wall 71 includes one or more holding portions 71h. The holding portion 71h holds a locked state between the metal cover 70 and the first structure 1A by engagement with the locking portion 56 of the first structure 1A. The holding portion 71h is, for example, an opening provided in the peripheral wall 71. The holding portion 71h may be a recess provided in the peripheral wall 71. The first structure 1A is maintained in a state of being attached to the metal cover 70 by the holding portion 71h of the metal cover 70 and the locking portion 56 of the first structure 1A.

### Ceiling Wall Portion

The ceiling wall portion 72 is a portion formed in a plate shape in the metal cover 70. The ceiling wall portion 72 is a plate portion extending in the horizontal direction. The ceiling wall portion 72 has a substantially rectangular shape extending in the X direction when viewed from the Z direction. The ceiling wall portion 72 forms a main portion of the metal cover 70. In the present embodiment, the ceiling wall portion 72 has a size that covers the entire first structure 1A from the +Z direction. As a result, the plurality of electronic components 10S and the plurality of bus bars 42 included in the first structure 1A are covered by the ceiling wall portion 72 from above. The ceiling wall portion 72 faces the upper surface of the base member 41S (the first surface 51a of the flat surface portion 51). The ceiling wall portion 72 is located on a side opposite to the cooling unit CM in the Z direction with respect to at least a part (for example, at least a part of each of the plurality of electronic components 10S and the plurality of bus bars 42) of the routing board 40S at least when the electrical connection unit 100 is mounted on the vehicle. The ceiling wall portion 72 is an example of a “first plate portion”.

The insertion portion 75 is a notch or an opening of the metal cover 70. The insertion portion 75 has an outer shape corresponding to a shape of the first auxiliary member 46 that supports the bus bar 42 or/and the connection bus bar 47 when viewed from the Z direction. In the present embodiment, some bus bars 42 are connected to the external connection bus bars 99 through the insertion portions 75 (see FIGS. 1 and 2). The connection bus bar 47 performs routing between the first structure 1A and the second structure 1B through the insertion portion 75 (see FIGS. 1 and 2). In the present embodiment, the metal cover 70 includes a plurality of insertion portions 75.

The ceiling wall portion 72 has a first surface 72a and a second surface 72b. The first surface 72a is a surface directed in the +Z direction. The first surface 72a is a flat surface along the horizontal direction. The first surface 72a faces the plurality of electronic components 10T included in the second structure 1B (see FIG. 9). The second surface 72b is located on a side opposite to the first surface 72a. The second surface 72b is a surface directed in the -Z direction. The second surface 72b is a flat surface along the horizontal direction. The second surface 72b faces the plurality of electronic components 10S included in the first structure 1A (see FIG. 9).

The ceiling wall portion 72 has the first end 72e1, the second end 72e2, the third end 72e3, and the fourth end 72e4 (see FIG. 3). The first end 72e1 and the second end 72e2 are a pair of ends of the metal cover 70 in the longitudinal direction and are separated from each other in the X direction. The third end 72e3 and the fourth end 72e4 are a pair of ends of the metal cover 70 in a lateral direction and are separated from each other in the Y direction.

### Fixing Portion

The fixing portion 73 is a fixing portion for directly fixing the electronic component 10S included in the first structure 1A to the metal cover 70 without interposing the base member 41S therebetween. The fixing portion 73 is provided at a position corresponding to the attachment portion 14 of each of the plurality of electronic component 10S when viewed from the Z direction. For example, in the present embodiment, the attachment portion 14 of the electronic component 10S, the fixing portion 73 of the metal cover 70, and the opening portion 53 of the routing board 40S overlap when viewed from the Z direction (see FIGS. 5, 9, 11, and the like). The fixing portion 73 of the metal cover 70 is, for example, a columnar or prismatic boss protruding in the -Z direction from the ceiling wall portion 72 toward the plurality of electronic components 10S of the first structure 1A. The fixing portion 73 of the metal cover 70 has the attachment hole 73h into which the fastening member 95 (for example, a screw or a bolt; and see FIG. 10) is inserted. The attachment hole 73h is open in the Z direction. The attachment hole 73h is an insertion hole through which the fastening member 95 passes.

### Holding Portion

As illustrated in FIG. 2, the holding portion 74 holds a locked state between the metal cover 70 and the second structure 1B by engagement with the locking portion 83 of the second structure 1B. The holding portion 74 includes a protruding portion 74PR. The protruding portion 74PR protrudes from a tip of the holding portion 74 in a direction intersecting the extending direction (-Z direction) of the arm portion 83AR. In the present embodiment, the protruding portion 74PR protrudes toward the second structure 1B. When the locking portion 83 approaches the holding portion 74, the protruding portion 74PR presses the protruding portion 83PR and elastically deforms the arm portion 83AR in a predetermined direction. Then, once the protruding portion 83PR reaches the holding portion 74, the arm portion 83AR is recovered from the deformed state, whereby the protruding portion 83PR and the protruding portion 74PR are locked. As a result, the cover member 41T of the second structure 1B is maintained in a state of being attached to the metal cover 70 (see FIG. 1).

### A7. Metal Block and Heat Transfer Member

Next, the metal block 110 and the heat transfer member 120 will be described with reference to FIG. 3.

The metal block 110 is a portion formed for improving a heat dissipation property. The metal block 110 is disposed between the ceiling wall portion 72 of the metal cover 70 and the routing board 40S. The metal block 110 forms at least a part of a heat transfer path HP thermally connecting the ceiling wall portion 72 of the metal cover 70 to the cooling unit CM. The metal block 110 has, for example, a columnar shape (for example, a cylindrical shape or a prismatic shape) along the Z direction. In the present disclosure, the “metal block” is not limited to a rectangular parallelepiped member and may include a member having a projecting portion to which a fastening member 131 described below is attached, a hole portion for accommodating a part of the fastening member 131, or the like. The metal block 110 is an example of a “second metal member”.

In the present embodiment, the metal block 110 is disposed at a position overlapping the bus bar 42B of the routing board 40S when viewed from the Z direction. In the present embodiment, the metal block 110 is fixed to the bus bar 42B of the routing board 40S and thermally connected to the bus bar 42B. For example, the metal block 110 is fixed to the horizontal plate portion 42p of the bus bar 42B. For example, the metal block 110 is fixed to the extending portion 63 of the bus bar 42B. The metal block 110 protrudes from the bus bar 42B of the routing board 40S toward the ceiling wall portion 72 of the metal cover 70. The bus bar 42B is an example of a “first routing member”.

In the present embodiment, the metal block 110 has an attachment hole 110h facing the bus bar 42B (see FIG. 6). The attachment hole 110h is opened at an end 110e1 of the metal block 110 on the -Z direction side and extends in the Z direction inside the metal block 110. An inner circumference of the attachment hole 110h has, for example, a screw groove.

The bus bar 42B has an attachment hole 132 facing the attachment hole 110h. The fastening member 131 (for example, a bolt or a screw) passes through the attachment hole 132 from the -Z direction side. As the fastening member 131 that has passed through the attachment hole 132 is engaged with the attachment hole 110h of the metal block 110, the metal block 110 is fixed to the bus bar 42B. However, the fixing of the metal block 110 to the bus bar 42B is not limited to the above example. For example, the attachment hole 110h may be a through-hole provided in the projecting portion of the metal block 110. In this case, the metal block 110 may be fixed to the bus bar 42B by the fastening member 131 that has passed through the attachment hole 110h and an engagement member (for example, a nut) engaged with a tip of the fastening member 131.

The metal block 110 is formed at a position surrounded by the peripheral wall 71 from the outside in the horizontal direction. The metal block 110 is disposed at a position different from the peripheral end of the ceiling wall portion 72 (for example, a position closer to the center than the peripheral end of the ceiling wall portion 72) when viewed from the Z direction and is provided away from the peripheral wall 71.

In the present embodiment, the metal block 110 is disposed at a position overlapping the second structure 1B when viewed from the Z direction. For example, the metal block 110 overlaps the cover member 41T when viewed from the Z direction. For example, the metal block 110 overlaps the electronic component 10T, the bus bar 42, or the bus bar 47 included in the second structure 1B when viewed from the Z direction.

In the present embodiment, the plurality of metal blocks 110 include a metal block 110A and a metal block 110B. For example, the metal block 110A is disposed between the electronic component 10A and the electronic component 10B when viewed from the Z direction (see FIG. 7). On the other hand, for example, the metal block 110B is disposed between the electronic component 10B and one bus bar 42 (for example, the bus bar 42G) included in the first structure 1A when viewed from the Z direction (see FIG. 7).

In the present embodiment, the heat transfer member 120 is provided between an end 110e2 of the metal block 110 on the +Z direction side and the ceiling wall portion 72 of the metal cover 70 (see FIG. 9). The heat transfer member 120 is, for example, a heat transfer sheet (for example, a thermally conductive silicone sheet) having elasticity. The heat transfer member 120 is made of a material having a higher thermal conductivity than the base member 41S or the cover member 41T. However, the heat transfer member 120 is not limited to the above example, and may be a heat transfer member formed of a thermally conductive gel or another material. The heat transfer member 120 has, for example, an insulating property. The heat transfer member 120 is an example of a “first heat transfer member”.

In the present embodiment, the heat transfer member 120 is in contact with each of the end 110e2 of the metal block 110 on the +Z direction side and the ceiling wall portion 72 of the metal cover 70. The heat transfer member 120 transfers, from the ceiling wall portion 72 of the metal cover 70 to the metal block 110, at least part of heat transferred from the second structure 1B to the ceiling wall portion 72 of the metal cover 70.

### A8. Fastening Structure Between First Structure and Metal Cover

As illustrated in FIG. 11, the metal cover 70 is disposed at a position covering the first structure 1A from the +Z direction. Thereafter, the first structure 1A is locked to the metal cover 70 by the locking portion 56 of the flat surface portion 51 of the base member 41S and the holding portion 71h of the peripheral wall 71 of the metal cover 70 (see FIG. 2). In a state in which the metal cover 70 and the first structure 1A are locked, the first structure 1A is supported by the metal cover 70 via the holding portion 71h. In FIG. 11, an insulating sheet 91A (described below) and a heat transfer member 92A (described below) in FIG. 3 are omitted.

After the locking, the fixing portion 73 of the metal cover 70 is located between the attachment portion 14 of each of the plurality of electronic components 10S included in the first structure 1A and the ceiling wall portion 72 of the metal cover 70. The plurality of electronic components 10S included in the first structure 1A are directly fixed to the metal cover 70 by the fastening members 95 passing through the opening portions 53 of the base member 41S (see FIGS. 2 and 11). In the present embodiment, the plurality of electronic components 10 (electronic components 10S) included in the first structure 1A are fixed to the metal cover 70 without sandwiching the base member 41S therebetween (that is, without interposing the base member 41S therebetween). In the first structure 1A, the electronic component 10S is electrically connected to the bus bar 42 via the connection component 20. The plurality of electronic components 10S are directly fixed to the metal cover 70, whereby the connection component 20 connected to the electronic component 10S and the bus bar 42 (including the bus bar 42 indirectly fixed to the electronic component 10S via another connection component 20) are suspended on the metal cover 70.

### A9. Connection Between First Structure and Second Structure

As illustrated in FIG. 10, the plurality of bus bars 42 included in the second structure 1B are disposed on the wall portion 81 of the cover member 41T. The plurality of electronic components 10T are attached to the arbitrary bus bars 42 from the +Z direction side. As illustrated in FIG. 2, one end of the connection bus bar 47 (connection bus bars 47A and 47B) is connected to any one of the plurality of bus bars 42 of the second structure 1B. With such a constitution, the connection bus bar 47 is attached to the second structure 1B.

The second structure 1B in which the connection bus bar 47 is incorporated is locked to the metal cover 70 by the locking portion 83 of the cover member 41T and the holding portion 74 of the metal cover 70. In a state in which the metal cover 70 and the second structure 1B are locked, the second structure 1B is supported by the metal cover 70. The other end of the connection bus bar 47 is connected to the bus bar 42 of the first structure 1A or the external connection bus bar 99. In the second structure 1B, the electronic component 10 and the bus bar 42 are not fixed to the cover member 41T. With such a constitution, the connection bus bar 47 connected to the bus bar 42 of the second structure 1B is movable in the horizontal direction. Since the connection bus bar 47 is movable in the horizontal direction, assembly tolerance occurring at the time of assembling the first structure 1A, the second structure 1B, and the metal cover 70 is absorbed. The first structure 1A and the second structure 1B are electrically connected in a state in which the assembly tolerance is absorbed by the connection bus bar 47.

### A10. Insulating Sheet and Heat Transfer Member

Next, the insulating sheet 91 and the heat transfer member 92 will be described.

### A10.1 Insulating Sheet

As illustrated in FIG. 3, the insulating sheet 91 is an insulating member for insulating the bus bar 42. The insulating sheet 91 has a sheet shape along the horizontal direction. The insulating sheet 91 is made of, for example, a synthetic resin such as polyester or polyimide, and has an insulating property.

The insulating sheet 91 includes the first insulating sheet 91A and a second insulating sheet 91B. As illustrated in FIG. 9, the first insulating sheet 91A has an outer shape corresponding to the lower surface of the base member 41S (the second surface 51b of the flat surface portion 51) in the Z direction. The first insulating sheet 91A is disposed between the external cooling unit CM and the routing board 40S. In the present embodiment, the first insulating sheet 91A is attached to a lower surface of the routing board 40S. The heat transfer member 92A is disposed immediately below the first insulating sheet 91A. Instead of the above example, the first insulating sheet 91A may be disposed between the external cooling unit CM and the heat transfer member 92 (for example, the heat transfer member 92A).

The second insulating sheet 91B is disposed immediately below the heat transfer member 92B. The heat transfer member 92B is disposed immediately below the bus bar 42 (bus bars 42K and 42M) that is exposed from the accommodation portion 82 toward the -Z direction (see FIG. 10).

### A10.2 Heat Transfer Member

As illustrated in FIG. 3, the heat transfer member 92 is a member for transferring heat generated by the electronic component 10 at the time of energization and/or heat (Joule heat) generated by the bus bar 42 itself at the time of energization to the external cooling unit CM and/or the metal cover 70. The heat transfer member 92 is, for example, a heat transfer sheet (for example, a thermally conductive silicone sheet) having elasticity. The heat transfer member 92 is made of a material having a higher thermal conductivity than the base member 41S or the cover member 41T. However, the heat transfer member 92 is not limited to the above example and may be a heat transfer member made of a thermally conductive gel or another material. The heat transfer member 92 includes the heat transfer member 92A and the heat transfer member 92B.

The heat transfer member 92A is disposed between the external cooling unit CM and the first insulating sheet 91A in the Z direction. At least a part of the heat transfer member 92A overlaps the electronic component 10S, the connection component 20, or the bus bar 42 when viewed from the Z direction. The heat transfer member 92A is disposed between the electronic component 10S, the connection component 20, or the bus bar 42 and the cooling unit CM. With such a constitution, the electronic component 10S included in the first structure 1A is thermally connected to the cooling unit CM via the bus bar 42 and the heat transfer member 92A. With such a constitution, heat dissipation of the electronic component 10S and the bus bar 42 included in the first structure 1A is promoted.

At least a part of the heat transfer member 92A overlaps the bus bar 42B to which the metal block 110 is fixed when viewed from the Z direction. The heat transfer member 92A is disposed between the bus bar 42B to which the metal block 110 is fixed and the cooling unit CM. With such a constitution, the electronic component 10T and the bus bar 42 included in the second structure 1B are thermally connected to the cooling unit CM via the ceiling wall portion 72 of the metal cover 70, the heat transfer member 120, the metal block 110, the bus bar 42B of the first structure 1A, and the heat transfer member 92A. With such a constitution, heat dissipation of the electronic component 10T and the bus bar 42 included in the second structure 1B is promoted.

One or more of the electronic component 10S, the connection component 20, and the bus bar 42 included in the first structure 1A may be thermally connected to the ceiling wall portion 72 of the metal cover 70 via a heat transfer member (not illustrated). In this case, at least a part of heat transferred from the electronic component 10S, the connection component 20, or the bus bar 42 included in the first structure 1A to the ceiling wall portion 72 of the metal cover 70 moves to the cooling unit CM via the heat transfer member 120 and the metal block 110.

On the other hand, the heat transfer member 92B is disposed immediately below the bus bar 42 (bus bars 42K and 42M) exposed from the accommodation portion 82 of the cover member 41T toward the -Z direction. The heat transfer member 92B thermally connects the bus bar 42 of the second structure 1B to the ceiling wall portion 72 of the metal cover 70.

### A11. Advantages

In the present embodiment, the electrical connection unit (for example, the electrical connection unit 100) is adjacent to the cooling unit (for example, the cooling unit CM) at least when mounted on the vehicle. The electrical connection unit includes the first routing structure (for example, the routing board 40S), the first metal member (for example, the metal cover 70), one or more electronic components (for example, the electronic component 10S), and the second metal member (for example, the metal block 110). The first routing structure includes one or more routing members (for example, the bus bars 42). The first routing structure faces the cooling unit. The first metal member includes the first plate portion (for example, the ceiling wall portion 72) located on a side opposite to the cooling unit with respect to at least a part of the first routing structure. The one or more electronic components are disposed between the first routing structure and the first plate portion. The second metal member is disposed between the first plate portion and the first routing structure, and forms at least a part of the heat transfer path (for example, the heat transfer path HP) thermally connecting the first plate portion and the first routing structure.

According to such a constitution, at least a part of heat generated by the electronic component or the first routing structure is transferred from the first routing structure to the cooling unit. With such an operation, it is possible to promote heat dissipation of the electronic component or the first routing structure. At least a part of heat transferred from the electronic component, the first routing structure, or another electronic component to the first plate portion of the first metal member is transferred to the cooling unit via the second metal member. With such an operation, it is possible to promote heat dissipation of the electronic component, the first routing structure, or another electronic component. Such operations can improve the heat dissipation property of the electrical connection unit.

In the present embodiment, the first metal member includes the second plate portion extending in the first direction from the peripheral end of the first plate portion. The second metal member is disposed at a position different from the peripheral end of the first plate portion when viewed from the first direction, and is provided away from the second plate portion. According to such a constitution, the heat transfer path formed by the second metal member is provided at a position different from the second plate portion. According to the constitution, heat is easily transferred from the first plate portion to the cooling unit. With such an operation, it is possible to further improve the heat dissipation property of the electrical connection unit.

In the present embodiment, the second metal member is disposed between the first electronic component (for example, the electronic component 10B) and one routing member (for example, the bus bar 42G) included in the one or more routing members when viewed from the first direction. According to such a constitution, it is possible to provide the heat transfer path formed by the second metal member inside the electrical connection unit while implementing high-density mounting of the electrical connection unit. With the constitution, it is possible to miniaturize the electrical connection unit and improve the heat dissipation property.

In the present embodiment, the second metal member is disposed between the first electronic component (for example, the electronic component 10B) and the second electronic component (the electronic component 10A) when viewed from the first direction. According to such a constitution, it is possible to provide the heat transfer path formed by the second metal member inside the electrical connection unit while implementing high-density mounting of the electrical connection unit. With the constitution, it is possible to miniaturize the electrical connection unit and improve the heat dissipation property.

In the present embodiment, the second metal member is fixed to the first routing member (for example, the bus bar 42B) and protrudes from the first routing member toward the first plate portion. According to such a constitution, the second metal member can transfer heat to the cooling unit by using a wide surface (large heat transfer area) of the first routing member. With such an operation, it is possible to further improve the heat dissipation property of the electrical connection unit.

In the present embodiment, the first routing member (for example, the bus bar 42B) includes the first connection portion (for example, the first connection portion 61), the second connection portion (for example, the second connection portion 62), and the extending portion (for example, the extending portion 63). The first connection portion is connected to the first electronic component (for example, the electronic component 10A). The second connection portion is connected to the second electronic component (for example, the electronic component 10B) or another routing member (for example, another bus bar 42, the bus bar 47, or the external connection bus bar 99). The extending portion extends between the first connection portion and the second connection portion. The second metal member is fixed to the extending portion. According to such a constitution, it is easy to reduce the size of a heat dissipation structure as compared with a case where the second metal member is fixed to the first connection portion or the second connection portion. With such an operation, it is possible to miniaturize the electrical connection unit.

In the present embodiment, the electrical connection unit includes the second routing structure (for example, the routing structure 40T), the third electronic component (for example, the electronic component 10T), and the second heat transfer member (for example, the heat transfer member 92B). The second routing structure faces the first plate portion from a side opposite to the first routing structure. The second heat transfer member is disposed between the first plate portion and the second routing structure or between the first plate portion and the third electronic component. According to such a constitution, at least a part of heat generated by the second routing structure or the third electronic component disposed on a side opposite to the first routing structure with respect to the first plate portion can be transferred to the cooling unit via the second metal member. With such an operation, it is possible to promote heat dissipation of the second routing structure or the third electronic component and further improve the heat dissipation property of the electrical connection unit.

### SECOND EMBODIMENT

Next, a second embodiment will be described. The second embodiment is different from the first embodiment in that a metal block 110 is fixed to a ceiling wall portion 72 of a metal cover 70 instead of a bus bar 42B. The constitution other than that described below is the same as that of the first embodiment.

### B1. Constitution

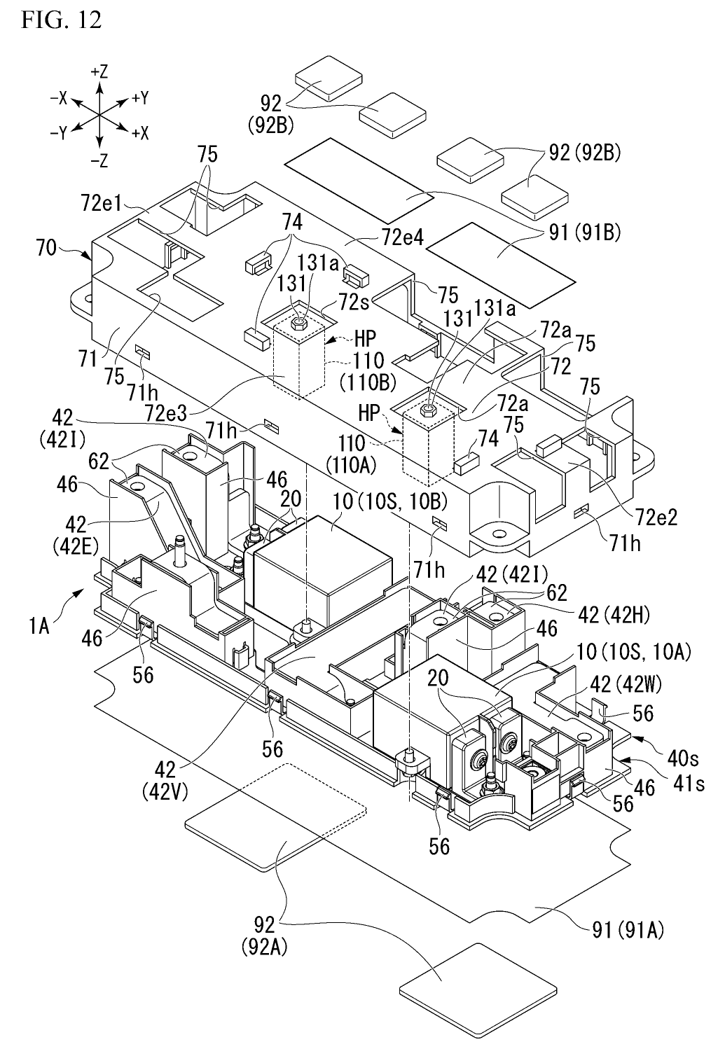

FIG. 12 is a partially exploded perspective view illustrating an electrical connection unit 100 according to the second embodiment. In the present embodiment, the metal block 110 is fixed to the ceiling wall portion 72 of the metal cover 70 and is thermally connected to the ceiling wall portion 72. The metal block 110 protrudes from the ceiling wall portion 72 of the metal cover 70 toward a routing board 40S. The ceiling wall portion 72 of the metal cover 70 may have a recess 72s for accommodating a head 131a of a fastening member 131 which is a bolt or a screw, for example. The recess 72s is recessed in the -Z direction compared to other portions of the ceiling wall portion 72 of the metal cover 70.

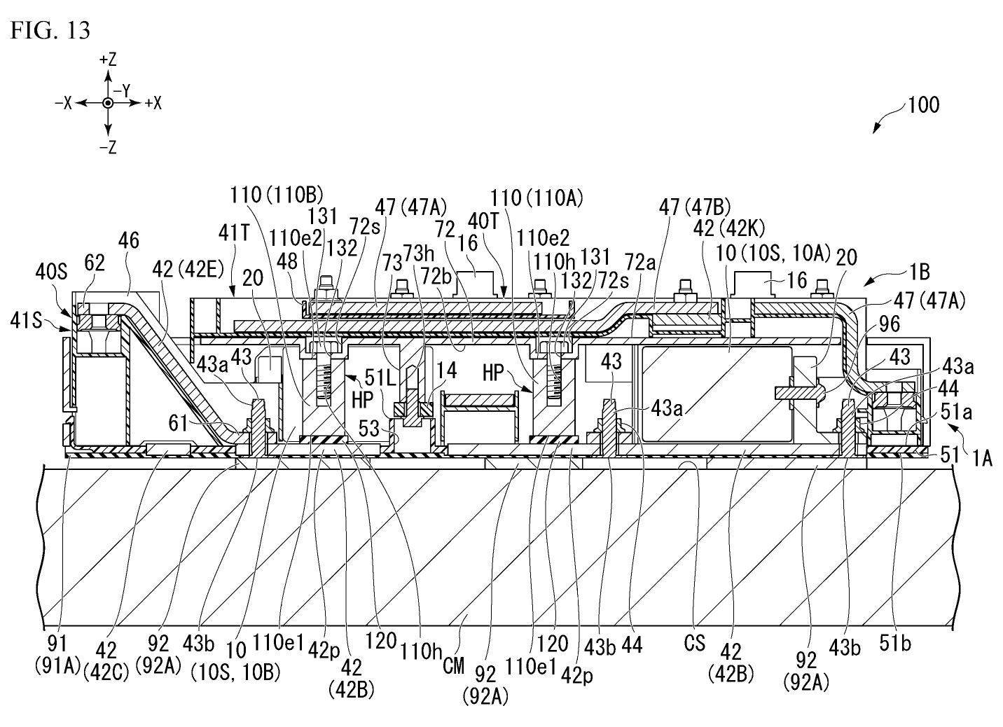

FIG. 13 is a cross-sectional view illustrating the electrical connection unit 100 according to the second embodiment. In the present embodiment, the metal block 110 has an attachment hole 110h facing the ceiling wall portion 72 of the metal cover 70. The attachment hole 110h is opened at an end 110e2 of the metal block 110 on the +Z direction side and extends in the Z direction inside the metal block 110. An inner circumference of the attachment hole 110h has, for example, a screw groove.

The ceiling wall portion 72 of the metal cover 70 has an attachment hole 132 facing the attachment hole 110h. The fastening member 131 (for example, a bolt or a screw) passes through the attachment hole 132. As the fastening member 131 that has passed through the attachment hole 132 is engaged with the attachment hole 110h of the metal block 110, the metal block 110 is fixed to the ceiling wall portion 72 of the metal cover 70. The fixing of the metal block 110 to the ceiling wall portion 72 of the metal cover 70 is not limited to the above example. For example, the attachment hole 110h may be a through-hole provided in the projecting portion of the metal block 110. In this case, the metal block 110 may be fixed to the ceiling wall portion 72 of the metal cover 70 by the fastening member 131 that has passed through the attachment hole 110h and an engagement member (for example, a nut) engaged with a tip of the fastening member 131.

The metal block 110 is disposed at a position overlapping the routing board 40S when viewed from the Z direction. In the present embodiment, the metal block 110 is disposed at a position overlapping the bus bar 42B when viewed from the Z direction. For example, the metal block 110 overlaps a horizontal plate portion 42p of the bus bar 42 when viewed from the Z direction. For example, a metal block 110A overlaps the horizontal plate portion 42p of the bus bar 42B when viewed from the Z direction. For example, the metal block 110 overlaps an extending portion 63 of the bus bar 42B when viewed from the Z direction. The bus bar 42B is an example of a “first routing member”.

In the present embodiment, a heat transfer member 120 is provided between an end 110e1 of the metal block 110 on the -Z direction side and an external cooling unit CM. The heat transfer member 120 is provided between the end 110e1 of the metal block 110 on -Z direction side and the horizontal plate portion 42p of the bus bar 42. That is, the heat transfer member 120 overlaps the metal block 110 from a side opposite to the ceiling wall portion 72 when viewed from the Z direction. The heat transfer member 120 is in contact with each of the end 110e1 of the metal block 110 on the -Z direction side and the horizontal plate portion 42p of the bus bar 42. The heat transfer member 120 moves, from the metal block 110 toward the external cooling unit CM, at least a part of heat transferred from a second structure 1B to the ceiling wall portion 72 of the metal cover 70 and transferred from the ceiling wall portion 72 to the metal block 110. For example, the heat transfer member 120 moves, to the bus bar 42 (for example, the bus bar 42B) of the routing board 40S, at least a part of heat transferred from the ceiling wall portion 72 to the metal block 110. In the present embodiment, the bus bar 42 (for example, the bus bar 42B) that is in contact with the heat transfer member 120 forms a part of a heat transfer path HP thermally connecting the ceiling wall portion 72 of the metal cover 70 to the cooling unit CM.

In the present embodiment, at least a part of a heat transfer member 92A overlaps the bus bar 42 (for example, the bus bar 42B) that is in contact with the heat transfer member 120 when viewed from the Z direction. The heat transfer member 92A is disposed between the cooling unit CM and the bus bar 42 (for example, the bus bar 42B) that is in contact with the heat transfer member 120. With such a constitution, an electronic component 10T and a bus bar 42 included in the second structure 1B are thermally connected to the cooling unit CM via the ceiling wall portion 72 of the metal cover 70, the metal block 110, the heat transfer member 120, the bus bar 42 of a first structure 1A, and the heat transfer member 92A. With such a constitution, heat dissipation of the electronic component 10T and the bus bar 42 included in the second structure 1B is promoted.

One or more of the electronic component 10S, the connection component 20, and the bus bar 42 included in the first structure 1A may be thermally connected to the ceiling wall portion 72 of the metal cover 70 via a heat transfer member (not illustrated). In this case, at least a part of heat transferred from the electronic component 10S, the connection component 20, or the bus bar 42 included in the first structure 1A to the ceiling wall portion 72 of the metal cover 70 moves to the cooling unit CM via the metal block 110 and the heat transfer member 120.

### B2. Advantages

In the present embodiment, the second metal member is fixed to the first plate portion and protrudes from the first plate portion toward the first routing structure. According to such a constitution, a structure of the first routing structure is more easily simplified, and the first routing structure is more easily thinned, as compared with a case where the second metal member is fixed to the first routing structure. With such a constitution, it is possible to achieve height reduction of the electrical connection unit.

In the present embodiment, the second metal member overlaps the first routing member, when viewed from the first direction from the first plate portion toward the cooling unit. The first routing member forms a part of the heat transfer path. According to such a constitution, the second metal member easily transfers heat to the cooling unit by using a wide surface (large heat transfer area) of the first routing member. With such an operation, it is possible to further improve the heat dissipation property of the electrical connection unit.

### B3. Modification Examples

Next, several modification examples of the second embodiment will be described below. Note that a constitution other than that described below in each modification example is the same as the constitution of the above-described second embodiment.

### B3.1 First Modification Example

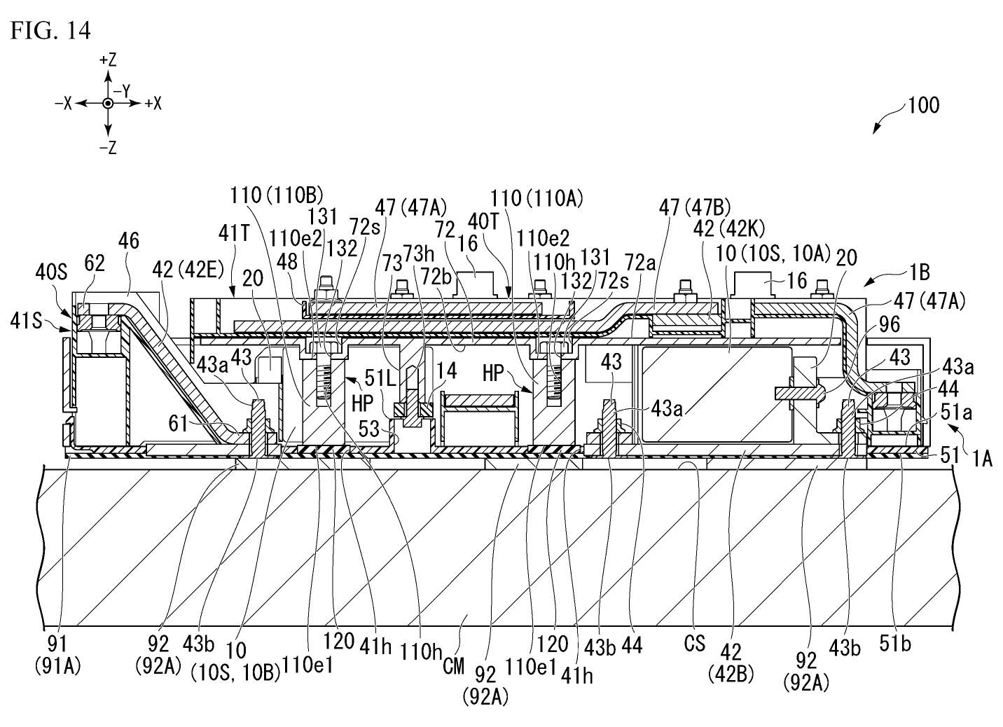

FIG. 14 is a cross-sectional view illustrating an electrical connection unit 100 according to a first modification example. In the first modification example, a metal block 110 is disposed at a position deviated from a bus bar 42 included in a routing board 40S when viewed from the Z direction. A flat surface portion 51 of a base member 41S of the routing board 40S has an opening portion 41h at a position corresponding to the metal block 110 in the Z direction. The opening portion 41h penetrates through the base member 41S in the Z direction.

In the present modification example, a heat transfer member 120 is disposed in the opening portion 41h of the base member 41S and exposed to the outside of the base member 41S (for example, to a lower side of the base member 41S). The heat transfer member 120 may be integrated with the base member 41S through insert molding, or may be separately formed and then attached to the base member 41S. The heat transfer member 120 is located between a tip 76e of a protruding portion 76 of a metal cover 70 on the -Z direction side and an external cooling unit CM.

According to such a constitution, heat can be moved closer to the cooling unit CM by the metal block 110 and the heat transfer member 120. Therefore, a heat dissipation property of the electrical connection unit may be further improved.

### B3.2 Second Modification Example

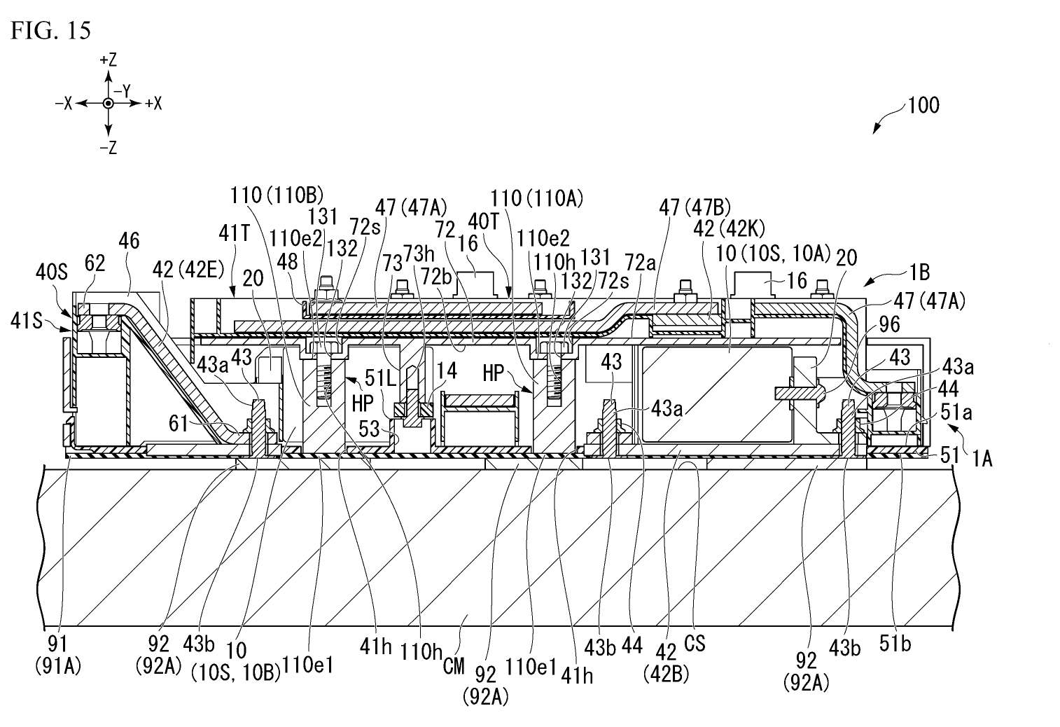

FIG. 15 is a cross-sectional view illustrating an electrical connection unit 100 according to a second modification example. In the second modification example, similarly to the first modification example, a metal block 110 of a metal cover 70 is disposed at a position deviated from a bus bar 42 included in a routing board 40S when viewed from the Z direction. A flat surface portion 51 of a base member 41S of the routing board 40S has an opening portion 41h at a position corresponding to the protruding portion 76 in the Z direction. The opening portion 41h penetrates through the base member 41S in the Z direction.

In the present modification example, an end of the metal block 110 on the -Z direction side is disposed in an opening portion 41h of the base member 41S and exposed to the outside of the base member 41S. A tip 76e of the metal block 110 on the -Z direction side is in contact with a heat transfer member 92A. The heat transfer member 92A is located between an end 110e1 of the metal block 110 in the -Z direction side and the external cooling unit CM. In the present modification example, the heat transfer member 92A is an example of the “first heat transfer member”.

According to such a constitution, heat can be moved closer to the cooling unit CM by the metal block 110. Therefore, a heat dissipation property of the electrical connection unit may be further improved.

As described above, the embodiment and the modification examples have been described. However, the embodiments and the modification examples are not limited to the examples described above. For example, a plurality of modification examples may be implemented in combination with each other. Additions, omissions, substitutions, and other modifications can be made without departing from the scope of the present invention.

### REFERENCE SIGNS LIST

100 Electrical connection unit

10, 10S, 10T Electronic component

40S Routing board (first routing structure)

41S Base member

41h Opening portion

40T Routing structure (second routing structure)

41T Cover member

42 Bus bar

70 Metal cover (first metal member)

71 Peripheral wall (second plate portion)

72 Ceiling wall portion (first plate portion)

92 Heat transfer member

92A Heat transfer member (first heat transfer member)

92B Heat transfer member (second heat transfer member)

110 Metal block (second metal member)

120 Heat transfer member (first heat transfer member)

What is claimed is:

1. An electrical connection unit that is adjacent to a cooling unit at least when mounted on a vehicle, the electrical connection unit comprising:
a first routing structure that includes one or more routing members and faces the cooling unit;
a first metal member that includes a first plate portion located on a side opposite to the cooling unit with respect to at least a part of the first routing structure;
one or more electronic components that are disposed between the first plate portion and the first routing structure; and
a second metal member that is disposed between the first plate portion and the first routing structure and forms at least a part of a heat transfer path thermally connecting the first plate portion and the cooling unit.

2. The electrical connection unit according to claim 1, wherein
in a case where a direction from the first plate portion toward the cooling unit is a first direction,
the first metal member includes a second plate portion extending in the first direction from a peripheral end of the first plate portion, and
the second metal member is disposed at a position different from the peripheral end of the first plate portion when viewed from the first direction and is provided away from the second plate portion.

3. The electrical connection unit according to claim 1, wherein
the one or more routing members include a first routing member, and
the second metal member is fixed to the first routing member and protrudes from the first routing member toward the first plate portion.

4. The electrical connection unit according to claim 3, wherein
the one or more electronic components include a first electronic component and a second electronic component,
the first routing member includes a first connection portion connected to the first electronic component, a second connection portion connected to the second electronic component or another routing member, and an extending portion extending between the first connection portion and the second connection portion, and
the second metal member is fixed to the extending portion.

5. The electrical connection unit according to claim 1, wherein
the second metal member is fixed to the first plate portion and protrudes from the first plate portion toward the first routing structure.

6. The electrical connection unit according to claim 5, wherein
the one or more routing members include a first routing member,
the second metal member overlaps the first routing member, when viewed from a first direction from the first plate portion toward the cooling unit, and
the first routing member forms a part of the heat transfer path.

7. The electrical connection unit according to claim 1, further comprising:
a second routing structure that faces the first plate portion from a side opposite to the first routing structure;
a third electronic component that faces the first plate portion from a side opposite to the first routing structure; and
a heat transfer member that is disposed between the first plate portion and the second routing structure or between the first plate portion and the third electronic component.
